(19) United States
(12) Patent Application Publication
(10) Pub. No.: US 2026/0367440 A1
(43) Pub. Date: Nov. 19, 2026

(54) DISPLAY PANEL AND DISPLAY APPARATUS

(71) Applicant: Wuhan Tianma Microelectronics Co., Ltd. Shanghai Branch, Shanghai (CN)

(72) Inventors: Ning KANG, Shanghai (CN); Nana Xiong, Shanghai (CN); Mengying Jiang, Shanghai (CN); Shengjuan Liu, Shanghai (CN); Chong Qian, Shanghai (CN)

(73) Assignee: Wuhan Tianma Microelectronics Co., Ltd. Shanghai Branch, Shanghai (CN)

(21) Appl. No.: 19/422,381

(22) Filed: Dec. 16, 2025

(30) Foreign Application Priority Data
May 19, 2025 (CN) 202510645214.2

(51) Int. Cl. G02F 1/1333; G02F 1/1335; G02F 1/1368; G09G 3/20; H10K 59/12; H10K 59/121

(52) U.S. Cl. CPC G02F 1/13338; G02F 1/133512; G02F 1/1368; G09G 3/2003; H10K 59/12; H10K 59/121

(57) ABSTRACT

Embodiments of the present application provides a display panel and a display apparatus. The display panel comprises a substrate, a pixel layer, and a color-resist layer. The pixel layer comprises a plurality of pixel units and a plurality of photosensitive units. The photosensitive units comprise photosensitive sensors. The color-resist layer is provided on a side of the pixel layer away from the substrate. The color-resist layer comprises an optical device overlapping with the photosensitive sensor. The optical device comprises a composite color-resist structure and a basic color-resist structure. The composite color-resist structure comprises at least two sub-color-resist structures stacked in a first direction which is the light-emitting direction of the display panel and having different filtering wavelength ranges. At least one sub-color-resist structure has the same material as at least one basic color-resist structure.

### CROSS-REFERENCE TO RELATED APPLICATIONS

This application claims priority to Chinese Patent Application No. 202510645214.2, titled “DISPLAY PANEL AND DISPLAY APPARATUS” and filed on May 19, 2025, which is hereby incorporated by reference in its entirety.

### TECHNICAL FIELD

The present application relates to the technical field of display, and in particular to a display panel and a display apparatus.

### BACKGROUND

With the continuous development of technology, the application scenarios of display panels are becoming increasingly broad. Display panels are now widely used in mobile phones, computers, televisions, wearable devices, and other devices. At the same time, the demand for display panels to have more diverse functions is also increasing. In related technologies, color temperature sensors, cameras, and other light-sensing devices are often integrated into the display panels.

### SUMMARY

Embodiments of the present application provide a display panel and a display apparatus.

In a first aspect, embodiments of the present application provide a display panel, which comprises a substrate, a pixel layer, comprising a plurality of pixel units and a plurality of photosensitive units, each of the plurality of photosensitive units comprising a photosensitive sensor; and a color-resist layer, provided on a side of the pixel layer away from the substrate, the color-resist layer comprising optical devices each of which overlaps with the photosensitive sensor, the optical devices comprising a composite color-resist structure and a basic color-resist structure, the composite color-resist structure comprising at least two sub-color-resist structures stacked in a first direction and having different filtering wavelength ranges, the first direction being a light-emitting direction of the display panel; at least one sub-color-resist structure is made of the same material as at least one basic color-resist structure.

In a second aspect, embodiments of the present application provide a display apparatus, which comprises the display panel as described in the embodiments of the first aspect.

The display panel provided in the embodiments of the present application comprises a substrate, a pixel layer, and a color-resist layer. The pixel layer comprises a plurality of pixel units, which can be used to emit light to realize the display operation of the display panel. The pixel layer further comprises a plurality of photosensitive units, the photosensitive unit comprises a photosensitive sensor used to sense light. The color-resist layer is provided on the side of the pixel layer away from the substrate. The color-resist layer comprises an optical device overlapping with the photosensitive sensor. One photosensitive sensor and one optical device overlapped can form one photosensitive channel. Light can pass through the optical device and then to the photosensitive sensor. That is, the light sensed by the photosensitive sensor in the single photosensitive channel can be light that has passed through the optical device.

The optical device comprises a composite color-resist structure and a basic color-resist structure. The composite color-resist structure and the basic color-resist structure can be configured to allow light of different wavelength ranges to pass through, so that the composite color-resist structure and the basic color-resist structure can be configured to form different photosensitive channels, respectively, to decompose ambient light into light in multiple wavelength ranges for sensing, thereby better improving the accuracy of the photosensitive operation of the display panel.

By configuring a composite color-resist structure comprising at least two sub-color-resist structures stacked in the first direction and having different filtering wavelength ranges, the intersection of the filtering wavelength ranges of the stacked sub-color-resist structures can be the filtering wavelength range of the composite color-resist structure, and the filtering wavelength range of the composite color-resist structure can be different from that of the sub-color-resist structures. This allows the photosensitive channel formed by the composite color-resist structure and the photosensitive sensor below the composite color-resist structure can be distinguishable from the photosensitive channels formed by the sub-color-resist structures. By configuring at least one sub-color-resist structure to be made of the same material as at least one basic color-resist structure, during the preparation of the display panel, at least one same color-resist material can be used to prepare one basic color-resist structure and one sub-color-resist structure in the composite color-resist structure. In this way, while using the composite color-resist structure, which is different from the basic color-resist structure, to form a new photosensitive channel, the accuracy of the photosensitive operation of the display panel can be improved, and the preparation of the composite color-resist structure can be facilitated, thereby facilitating the preparation of the display panel.

### BRIEF DESCRIPTION OF THE DRAWINGS

In order to more clearly illustrate the technical solutions of the embodiments of the present application, the following briefly introduces the drawings required for use in the embodiments of the present application. Obviously, the drawings described below are only some embodiments of the present application. For those skilled in the art, other drawings can be obtained based on these drawings without creative work.

FIG. 1 is a schematic structural diagram of a display panel provided in an embodiment of the present application;

FIG. 2 is a partial cross-sectional view of a display panel provided in an embodiment of the present application;

FIG. 3 is a partial cross-sectional view of a display panel provided in another embodiment of the present application;

FIG. 4 is a schematic structural diagram of a photosensitive circuit provided in an embodiment of the present application;

FIG. 5 is a partial cross-sectional view of a display panel provided in yet another embodiment of the present application;

FIG. 6 is a partial cross-sectional view of a display panel provided in yet another embodiment of the present application;

FIG. 7 is a partial cross-sectional view of a display panel provided in yet another embodiment of the present application;

FIG. 8 is normalized transmittance spectrums of optical devices provided in an embodiment of the present application;

FIG. 9 is a schematic diagram of a color matching function obtained by fitting a first channel, a second channel, and a third channel provided in an embodiment of the present application;

FIG. 10 is a schematic diagram of a color matching function obtained by fitting a first channel, a second channel, a third channel, and a transparent channel according to an embodiment of the present application;

FIG. 11 is a schematic diagram of a color matching function obtained by fitting a first channel, a second channel, a third channel, a composite channel, and a transparent channel according to an embodiment of the present application;

FIG. 12 is a schematic diagram of fitting coefficients of a color matching function obtained by fitting data of photosensitive channels provided in an embodiment of the present application;

FIG. 13 is a partial cross-sectional view of a display panel provided in yet another embodiment of the present application;

FIG. 14 is a partial structural schematic diagram of an optical device provided in an embodiment of the present application;

FIG. 15 is a partial structural schematic diagram of an optical device provided in another embodiment of the present application;

FIG. 16 is a partial cross-sectional view of a display panel provided in yet another embodiment of the present application;

FIG. 17 is a partial structural schematic diagram of an optical device provided in yet another embodiment of the present application;

FIG. 18 is a partial structural schematic diagram of an optical device provided in yet another embodiment of the present application;

FIG. 19 is a partial cross-sectional view of a display panel provided in yet another embodiment of the present application;

FIG. 20 is a partial cross-sectional view of a display panel provided in yet another embodiment of the present application;

FIG. 21 is a partial cross-sectional view of a display panel provided in yet another embodiment of the present application;

FIG. 22 is a partial structural schematic diagram of a color-resist layer provided in an embodiment of the present application;

FIG. 23 is a partial structural schematic diagram of a color-resist layer provided in another embodiment of the present application;

FIG. 24 is a partial structural schematic diagram of a color-resist layer provided in yet another embodiment of the present application;

FIG. 25 is a partial structural schematic diagram of a color-resist layer provided in yet another embodiment of the present application;

FIG. 26 is a partial structural schematic diagram of a color-resist layer provided in yet another embodiment of the present application; and

FIG. 27 is a schematic structural diagram of a display panel provided in another embodiment of the present application.

### REFERENCE NUMERALS

10—display panel;
100—substrate;
200—array layer; 200a—first insulating layer; 200b—second insulating layer; 200c—third insulating layer; 200d—planarization layer; 200da—first planarization layer; 200db—second planarization layer; 210—pixel circuit; 211—transistor; 211a—gate; 211b—source-drain; 212—storage capacitor; 212a—first plate; 212b—second plate; 220—photosensitive sensor; 221—first sensing electrode; 222—second sensing electrode; 223—semiconductor structure;
300—light-emitting layer; 300a—light-transmitting opening; 310—light-emitting unit; 310a—red light-emitting unit; 310b—green light-emitting unit; 310c—blue light-emitting unit; 311—first electrode; 312—light-emitting functional layer; 312a—first common layer; 312b—light-emitting structure; 312c—second common layer; 313—second electrode;
400—pixel defining layer; 400a—third opening; 400b—fourth opening;
500—encapsulation layer; 510—first encapsulation layer; 520—second encapsulation layer; 530—third encapsulation layer;
600—touch functional layer;
700—color-resist layer; 710—optical device; 711—composite color-resist structure; 711a—sub-color-resist structure; 712—basic color-resist structure; 712a—first-type color-resist structure; 712b—second-type color-resist structure; 712c—third-type color-resist structure; 713—transparent structure; 720—color-resist device; 721—red color-resist structure; 722—green color-resist structure; 723—blue color-resist structure;
800—light-shielding layer; 800a—first opening; 800b—second opening;
900—optically transparent adhesive layer;
T1—first transistor; T2—second transistor; T3—third transistor;
L1—first power signal line; L2—second power signal line; L3—reset pulse signal line; L4—read control signal line;
DP—dummy light-emitting unit; DP1—first dummy electrode; DP2—light-emitting material layer; DP3—second dummy electrode;
LG—optical device group;
ST—photosensitive channel; ST1—first channel; ST2—second channel; ST3—third channel; ST4—composite channel; ST5—transparent channel;
GL—green color-resist column; BRL—blue-red color-resist column;
AA—display area; AA1—center area; AA2—edge area; NA—non-display area; NA1—dummy pixel area;
X—first direction; Y—second direction; Z—third direction.

### DETAILED DESCRIPTION

Features and exemplary embodiments of various aspects of the present application will be described in detail below. In the detailed description below, many specific details are proposed to provide a comprehensive understanding of the present application. However, it is obvious to those skilled in the art that the present application can be implemented without the need for some of these specific details. The following description of the embodiments is only intended to provide a better understanding of the present application by illustrating examples of the present application. In the accompanying drawings and the following description, at least part of the known structures and technologies are not shown to avoid unnecessary ambiguity in the present application; and, for clarity, the size of some structures may be exaggerated. In addition, features, structures, or characteristics described below may be combined in one or more embodiments in any suitable manner.

It should be noted that, herein, unless otherwise specified, the meaning of “a plurality of” is more than two; the terms “upper”, “lower”, “left”, “right”, “inside”, “outside”, etc., indicating directions or positional relationships, are only for the convenience of describing this application and simplifying the description, and do not indicate or imply that the devices or elements referred to must have a specific direction, be constructed and operate in a specific direction, and therefore should not be understood as limiting this application. In addition, relational terms such as first and second, etc. are merely used to distinguish one entity or operation from another entity or operation, and do not necessarily require or imply that there is any such actual relationship or order between these entities or operations. Moreover, the terms “comprise”, “include” or any other variations thereof are intended to cover non-exclusive inclusion, so that a process, method, article, or device that comprises a series of elements comprises not only those elements, but also other elements not explicitly listed, or also comprises elements inherent to such process, method, article, or device. In the absence of further limitations, the elements defined by the sentence “comprise . . . ” do not exclude the presence of other identical elements in the process, method, article, or device that comprises the elements.

The directional words that appear in the following description refer to the directions shown in the drawings and do not limit the specific structure of the embodiments of this application. It should also be noted that in the description of this application, unless otherwise specified or limited, the terms “installation” and “connection” should be understood broadly. For example, they can mean a fixed connection, a detachable connection, or an integral connection; they can be directly connected or indirectly connected. For those of ordinary skilled in the art, the specific meanings of the above terms in this application can be understood according to the specific circumstances.

With the continuous advancement of technology, the application scenarios of display panels are becoming increasingly broad. Display panels are now widely used in mobile phones, computers, televisions, wearable devices, and other devices. At the same time, the demand for display panel functionality is also increasing. Color temperature sensors, cameras, and other light-sensing devices (for example, photosensitive sensors can be used to detect light intensity at different wavelengths) are often integrated into the display panels.

Exemplarily, the photosensitive devices in the display panel may comprise a color temperature sensor, that is, the photosensitive devices in the display panel can be configured to sense the brightness and color temperature of the ambient light around the display panel, so that when the device is taking pictures and the display panel is displaying, the display brightness and color temperature of the device can be adjusted according to the brightness and color temperature of the ambient light sensed by the color temperature sensor, thereby improving the device's photography performance and display effect.

Specifically, the overlapping photosensitive sensors and color-resist structures in the color temperature sensor can form photosensitive channels. There can be multiple photosensitive channels, and different types of photosensitive channels can have color-resists made of different materials. This allows different photosensitive channels to sense the intensity of light of different wavelengths, thereby decomposing ambient light into multiple wavelength ranges for sensing. When the display panel detects brightness and color temperature, color matching functions (CMFs) can be obtained by fitting the transmittance spectra of each photosensitive channel. For example, the color matching functions can be obtained by fitting the transmittance spectra of each photosensitive channel and the external quantum efficiency (EQE) of the photosensitive sensor. Then, the tristimulus values measured by the color temperature sensor are derived based on the fitted color matching functions and the electrical signals generated when each photosensitive channel senses ambient light. Thus, the ambient color temperature and brightness can then be calculated from the tristimulus values.

The color temperature sensor's accuracy in detecting color temperature and brightness depends on the fitting accuracy when the transmission spectrum of each photosensitive channel fits the color matching function, and the number of types of photosensitive channels in the color temperature sensor affects the fitting accuracy when the color temperature sensor fits the color matching function. Therefore, increasing the number of types of photosensitive channels in the color temperature sensor can decompose ambient light into light in a larger number of wavelength ranges for sensing, thereby better improving the fitting accuracy of the color temperature sensor when fitting the color matching function.

However, since the photosensitive channels in the embedded color temperature sensor in the related art (for example, the photosensitive sensor of the embedded color temperature sensor is integrated into the array layer or the light-emitting layer, and the material of at least part of the color-resist structure of the embedded color temperature sensor is the same as the color-resist material used for display in the display area) often only comprise a red photosensitive channel (for example, the color-resist structure in the red photosensitive channel may be red color-resist, and the material of the red color-resist is the same as the red color-resist material used for display in the display area), a green photosensitive channel (for example, the color-resist structure in the green photosensitive channel may be green color-resist, and the material of the green color-resist is the same as the green color-resist material used for display in the display area), and a blue photosensitive channel (for example, the color-resist structure in the blue photosensitive channel may be blue color-resist, and the material of the blue color-resist is the same as the blue color-resist material used for display in the display area), there is a certain error between the color matching function fitted by the color temperature sensor in the related art and the CIE color matching function, thereby resulting in poor accuracy of the photosensitive operation of the display panel.

In order to solve the above technical problems, the present application is provided. In order to better understand the present application, the display panel and the display apparatus of the present application are described in detail below with reference to the accompanying drawings.

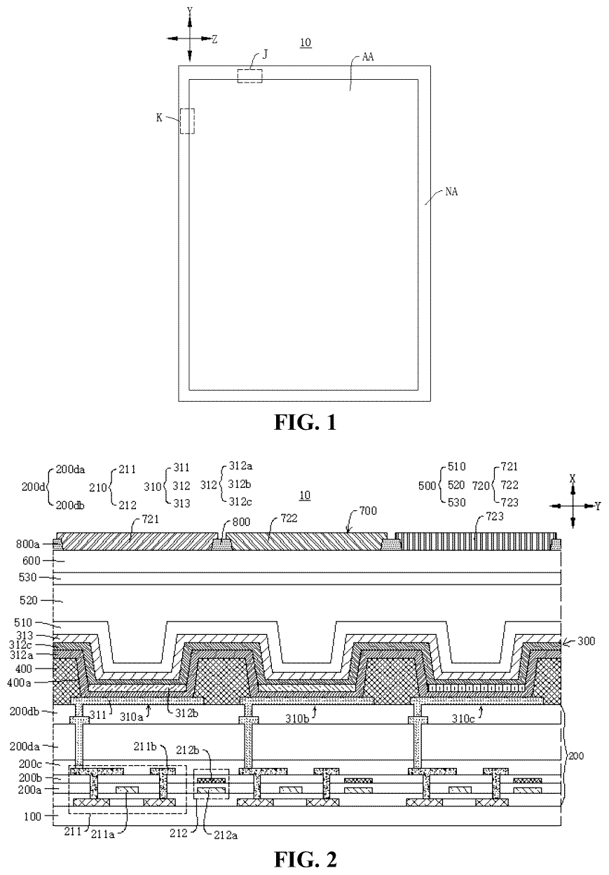

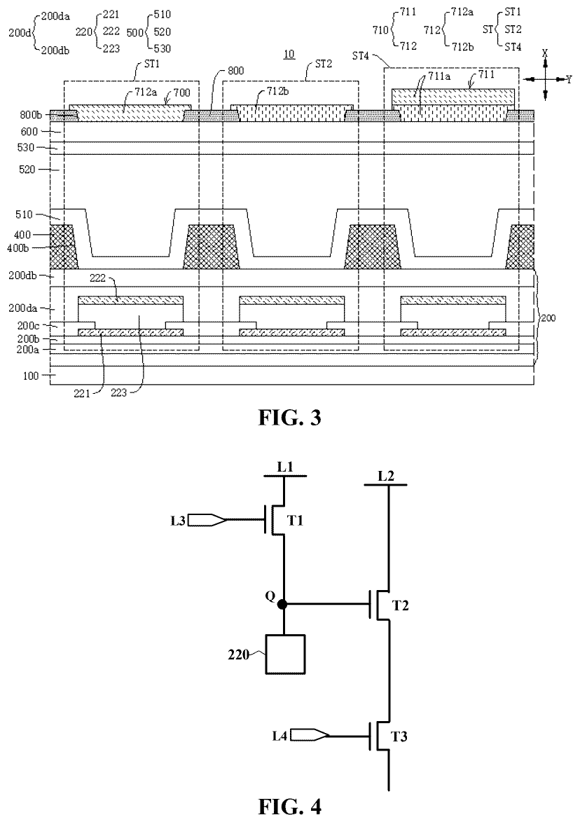

FIG. 1 is a schematic structural diagram of a display panel 10 provided in an embodiment of the present application. FIG. 2 is a partial cross-sectional view of a display panel 10 provided in an embodiment of the present application. FIG. 3 is a partial cross-sectional view of a display panel 10 provided in another embodiment of the present application. The X direction in the drawings may represent the first direction X, the Y direction in the drawings may represent the second direction Y, and the Z direction in the drawings may represent the third direction Z. The first direction X, the second direction Y, and the third direction Z may intersect with each other. For example, the first direction X, the second direction Y, and the third direction Z may be perpendicular to each other.

As shown in FIGS. 1 to 3, embodiments of the present application provide a display panel 10. The display panel 10 comprises a substrate 100, a pixel layer, and a color-resist layer 700. The pixel layer comprises a plurality of pixel units and a plurality of photosensitive units. The photosensitive unit comprises a photosensitive sensor 220. The color-resist layer 700 is provided on a side of the pixel layer away from the substrate 100. The color-resist layer 700 comprises an optical device 710 overlapping with the photosensitive sensors 220. The optical device 710 comprises a composite color-resist structure 711 and a basic color-resist structure 712. The composite color-resist structure 711 comprises at least two sub-color-resist structures 711a stacked in the first direction X and having different filtering wavelength ranges. The first direction X is the light-exiting direction of the display panel 10. At least one sub-color-resist structure 711a is made of the same material as at least one basic color-resist structure 712.

The display panel 10 provided in embodiments of the present application comprises a substrate 100, a pixel layer, and a color-resist layer 700.

Optionally, the display panel 10 provided in the embodiments of the present application may be provided in a variety of types and configurations. For example, the display panel 10 provided in the embodiments of the present application may be a display panel 10 that operates based on the organic light-emitting diode (OLED) display principle or a display panel 10 that operates based on the light-emitting diode (LED) display principle.

For the convenience of description, the following embodiments are described by taking the display panel 10 provided in the embodiments of the present application as an example to illustrate the operation based on the organic light-emitting diode display principle.

The pixel layer comprises a plurality of pixel units configured to emit light to realize the display operation of the display panel 10.

Optionally, the pixel unit may comprise a pixel circuit 210 and a light-emitting unit 310 electrically connected to the pixel circuit 210. For example, the pixel layer may comprise an array layer 200 and a light-emitting layer 300 provided on a side of the array layer 200 away from the substrate 100. The array layer 200 may comprise multiple pixel circuits 210, and the light-emitting layer 300 may comprise multiple light-emitting units 310. A single light-emitting unit 310 may be electrically connected to a single pixel circuit 210 to form a single pixel unit. The pixel circuit 210 may be configured to drive the light-emitting unit 310 to emit light.

Optionally, the first direction X is the light-exiting direction of the display panel 10, which may mean that the first direction X may be the light-exiting direction of the light-emitting unit 310 when the pixel circuit 210 in the display panel 10 drives the light-emitting unit 310 to emit light. Exemplarily, the light-exiting direction of the display panel 10 may be the direction from the substrate 100 to the pixel layer, that is, the first direction X may be the direction from the substrate 100 to the pixel layer.

Optionally, the pixel circuit 210 may comprise a transistor 211, a storage capacitor 212, and drive signal lines for connecting various components. The transistor 211 may comprise a semiconductor, a gate 211a, and a source-drain 211b. The storage capacitor 212 may comprise a first plate 212a and a second plate 212b. A part of transistors 211 in the driver circuit may be connected to the anodes of the light-emitting units 310, allowing the driver circuit to provide a drive current to the light-emitting unit 310 to drive the light-emitting unit 310 to emit light.

Optionally, in a direction away from the substrate 100, the array layer 200 may further comprise a first insulating layer 200a, a second insulating layer 200b, and a third insulating layer 200c stacked in sequence. As an example, the gate 211a and the first electrode 212a may be located on a side of the first insulating layer 200a facing the substrate 100, the second electrode 212b may be located between the first insulating layer 200a and the second insulating layer 200b, and the source-drain 211b may be located between the second insulating layer 200b and the third insulating layer 200c.

Optionally, the array layer 200 may further comprise a planarization layer 200d provided on a side of the third insulating layer 200c facing away from the substrate 100, and the light-emitting layer 300 may be provided on a side of the planarization layer 200d facing away from the substrate 100.

Optionally, in a direction away from the substrate 100, the light-emitting unit 310 may comprise a first electrode 311, a light-emitting functional layer 312, and a second electrode 313 stacked in sequence.

Optionally, the light-emitting functional layer 312 may comprise a first common layer 312a, a second common layer 312c provided on a side of the first common layer 312a facing away from the substrate 100, and a light-emitting structure 312b provided between the first common layer 312a and the second common layer 312c. For example, the first common layer 312a may comprise a hole injection layer (HIL) and a hole transport layer (HTL), and the second common layer 312c may comprise an electron injection layer (EIL) and an electron transport layer (ETL).

Optionally, the first electrode 311 and the second electrode 313 can serve as pixel electrodes of the display panel 10. One of the first electrode 311 and the second electrode 313 can serve as an anode, and the other can serve as a cathode to drive the light-emitting functional layer 312 to emit light. In the embodiments of the present application, as an example, the first electrode 311 serves as the anode of the display panel 10, and the second electrode 313 serves as the cathode of the display panel 10.

Optionally, the second electrodes 313 of each of the light-emitting units 310 may be electrically connected to each other, thereby facilitating control of the display panel 10. Exemplarily, the second electrodes 313 of the light-emitting units 310 may be integrally formed.

Optionally, the first common layers 312a of the light-emitting units 310 may be integrally formed, and the second common layers 312c of the light-emitting units 310 may be integrally formed, so as to facilitate the preparation of the display panel 10.

Optionally, the light-emitting units 310 may comprise a red light-emitting unit 310a for emitting red light, a green light-emitting unit 310b for emitting green light, and a blue light-emitting unit 310c for emitting blue light, so as to realize a color light-emitting display of the display panel 10. The light-emitting structures 312b of the light-emitting units 310 having different light-emitting colors are made of different materials.

Optionally, the display panel 10 may have a display area AA and a non-display area NA provided around the display area AA. Exemplarily, the light-emitting unit 310 and the pixel circuit 210 may be provided in the display area AA.

Optionally, the display panel 10 may further comprise an encapsulation layer 500 provided on a side of the light-emitting layer 300 facing away from the substrate 100. The encapsulation layer 500 may be configured to encapsulate the light-emitting unit 310, thereby better improving the operating stability of the display panel 10.

For example, in a direction away from the substrate 100, the encapsulation layer 500 may comprise a first encapsulation layer 510, a second encapsulation layer 520, and a third encapsulation layer 530 stacked in sequence. The first encapsulation layer 510 may be made of an inorganic material and may be prepared by a chemical vapor deposition (CVD) process. This allows the first encapsulation layer 510 to have good encapsulation capabilities, thereby reducing the impact of water vapor on the light-emitting layer 300. The second encapsulation layer 520 may be made of an organic material and may be prepared by inkjet printing (IJP). This allows the material of the second encapsulation layer 520 to have better flowability during the preparation of the display panel 10, and the surface of the second encapsulation layer 520 facing away from the substrate 100 to be relatively flat, facilitating the subsequent preparation of other devices on the encapsulation layer 500. The third encapsulation layer 530 may be made of an inorganic material. The third encapsulation layer 530 may be prepared by a chemical vapor deposition process, so that the third encapsulation layer 530 has good encapsulation capability to further reduce the impact of water vapor on the light-emitting layer 300.

Optionally, the display panel 10 may further comprise a touch functional layer 600 provided on a side of the encapsulation layer 500 facing away from the substrate 100. The touch functional layer 600 may be configured to implement touch control of the display panel 10. For example, the touch functional layer 600 may comprise touch electrodes and a touch insulation layer (not shown). The touch electrodes may be configured to sense the touch of a user's finger, and the touch insulation layer may be configured to protect the touch electrodes and prevent crosstalk between different types of touch electrodes.

The pixel layer further comprises a plurality of photosensitive units, and the photosensitive unit comprises photosensitive sensors 220 configured to sense light.

Optionally, there are multiple ways to set the position of the photosensitive sensor 220.

For example, the photosensitive sensor 220 may be located in the same film layer (not shown) as the light-emitting unit 310, that is, the light-emitting layer 300 may comprise the photosensitive sensor 220. Exemplarily, in a direction away from the substrate 100, the photosensitive sensor 220 may comprise a first photosensitive electrode, a photoelectric conversion structure, and a second photosensitive electrode stacked in sequence. The first photosensitive electrode may be located in the same film layer as the first electrode 311, the photoelectric conversion structure may be located in the same film layer as any film layer in the light-emitting functional layer 312, and the second photosensitive electrode may be located in the same film layer as the second electrode 313.

As another example, the photosensitive sensor 220 and the pixel circuit 210 may be located in the same film layer (as shown in FIGS. 2 and 3), that is, the array layer 200 may comprise the photosensitive sensor 220.

For ease of description, the following embodiments are described by taking the array layer 200 comprising the photosensitive sensor 220 as an example.

By providing the array layer 200 comprising the photosensitive sensor 220, that is, by integrating the sensor for sensing light into the array layer 200, it is possible to eliminate the need to provide an external sensor for sensing light, thereby reducing the thickness of the display panel 10. Furthermore, during the preparation process of the display panel 10, at least part of the film layers of the photosensitive sensor 220 can be prepared together with other film layers of the array layer 200, thereby reducing the cost of the display panel 10 and improving the preparation efficiency of the display panel 10. For example, during the preparation process of the display panel 10, a part of the film layers of the photosensitive sensor 220 can be prepared together with the film layers in the same layer as the part of film layers in the photosensitive sensor 220 in the transistor 211.

Optionally, the photosensitive sensor 220 can be any sensor capable of sensing light intensity. Exemplarily, the photosensitive sensor 220 may comprise a photodiode. The photodiode may comprise a first sensing electrode 221, a second sensing electrode 222, and a semiconductor structure 223 provided between the first sensing electrode 221 and the second sensing electrode 222. The first sensing electrode 221 can be located on a side of the second sensing electrode 222 facing the substrate 100. In a direction from the first sensing electrode 221 to the second sensing electrode 222, the semiconductor structure 223 may comprise an N-type semiconductor layer, an intrinsic layer, and a P-type semiconductor layer stacked in sequence. This allows the current between the first sensing electrode 221 and the second sensing electrode 222 to change as the light irradiating the semiconductor structure 223 changes, thereby enabling the photosensitive sensor 220 to sense light.

Optionally, there are various ways to position the photosensitive sensor 220 in the array layer 200. For example, the first sensing electrode 221 can be provided in the same layer as the source-drain 211b of the transistor 211. That is, the first sensing electrode 221 can be located between the second insulating layer 200b and the third insulating layer 200c. The semiconductor structure 223 can be located between the third insulating layer 200c and the planarization layer 200d. The third insulating layer 200c can be provided with a via hole, and the semiconductor structure 223 can be connected to the first sensing electrode 221 through the via hole. The second sensing electrode 222 can also be located between the third insulating layer 200c and the planarization layer 200d.

Optionally, the planarization layer 200d may comprise a first planarization layer 200da and a second planarization layer 200db located on a side of the first planarization layer 200da facing away from the substrate 100. The semiconductor structure 223 and the second sensing electrode 222 may both be located between the third insulating layer 200c and the first planarization layer 200da. The light-emitting layer 300 may be located on a side of the second planarization layer 200db facing away from the substrate 100.

Optionally, the photosensitive unit may further comprise a photosensitive circuit connected to the photosensitive sensor 220. A single photosensitive sensor 220 may be connected to a single photosensitive circuit to form a single photosensitive unit. The photosensitive sensor 220 may be configured to convert a light signal into an electrical signal, and the photosensitive circuit may be configured to convert the electrical signal received by the photosensitive sensor 220 into a detection signal. By determining the magnitude of the detection signal, the strength of the light signal sensed by the photosensitive unit may be determined, thereby enabling photosensitive operations such as color temperature sensing.

Optionally, the array layer 200 may comprise a photosensitive circuit.

FIG. 4 is a schematic structural diagram of a photosensitive circuit provided in an embodiment of the present application.

Optionally, there are various ways to configure the structure of the photosensitive circuit. As an example, as shown in FIG. 4, the photosensitive circuit may comprise a first transistor T1, a second transistor T2, and a third transistor T3. The display panel 10 may further comprise a first power signal line L1, a second power signal line L2, a reset pulse signal line L3, and a read control signal line L4.

The control terminal of the first transistor T1 is electrically connected to the reset pulse signal line L3, the first terminal of the first transistor T1 and the control terminal of the second transistor T2 are electrically connected to the first node Q, one of the first sensing electrode 221 and the second sensing electrode 222 of the photosensitive sensor 220 is also electrically connected to the first node Q, the second terminal of the first transistor T1 is electrically connected to the first power signal line L1, the first terminal of the second transistor T2 is electrically connected to the second power signal line L2, the second terminal of the second transistor T2 is electrically connected to the first terminal of the third transistor T3, and the control terminal of the third transistor T3 is electrically connected to the read control signal line L4.

The reset pulse signal line L3 is configured to output a reset pulse signal, which may comprise alternating first level and second level. The read control signal line L4 is configured to provide a read control signal with preset timing to control the third transistor T3 to output or stop outputting a detection signal. The second transistor T2 is configured to convert the signal at the first node Q into a detection signal, and the third transistor T3 is configured to output the detection signal in response to the control of the read control signal line L4. The second terminal of the third transistor T3 serves as the output terminal of the detection signal.

Exemplarily, the operation process of the photosensitive circuit may comprise a reset phase and a read phase.

In the reset phase, the reset pulse signal line L3 outputs the first level, controls the first transistor T1 to be turned on, and the first power signal Vrst provided by the first power signal line L1 is transmitted to the first node Q through the first transistor T1, while charging the capacitor in the photodiode 11, so that the potential of the first node Q is reset.

During the read phase, the reset pulse signal line L3 outputs a second level, controlling the first transistor T1 to turn off. The photodiode 11 receives the light signal and converts it into an electrical signal, forming a photocurrent. The capacitor inside the photosensitive sensor 220 discharges, and the potential of the first node Q gradually decreases. The read control signal line L4 outputs a read control signal, turning on the third transistor T3. The second power supply signal VDD provided by the second power signal line L2 flows through the second transistor T2 and the third transistor T3 to the second terminal of the third transistor T3 and is output. The second transistor T2 operates in a linear region, and its degree of conduction determines the potential of the second terminal of the third transistor T3. The conduction degree of the second transistor T2 is determined by the voltage of the first node Q. That is, the potential of the first node Q determines the potential of the second terminal of the third transistor T3. The magnitude of the photocurrent of the photosensitive sensor 220 is determined by the light intensity it receives. Therefore, the potential of the second terminal of the third transistor T3 varies under different light intensities, thereby achieving the light sensing function.

A color-resist layer 700 is provided on a side of the pixel layer away from the substrate 100. The color-resist layer 700 comprises an optical device 710 overlapping with the photosensitive sensor 220. A single photosensitive sensor 220 and a single optical device 710 that overlap can form a single photosensitive sensor channel ST. Light can pass through the optical device 710 to the photosensitive sensor 220. That is, the light sensed by the photosensitive sensor 220 in the single photosensitive sensor channel ST can be the light that has passed through the optical device 710.

Optionally, there are various ways to position the color-resist layer 700. For example, the color-resist layer 700 can be provided on a side of the encapsulation layer 500 facing away from the substrate 100. This allows the encapsulation layer 500 to protect the light-emitting layer 300 below the encapsulation layer 500 during the preparation of the color-resist layer 700, making the light-emitting layer 300 less susceptible to damage.

Optionally, the color-resist layer 700 may be provided on a side of the touch functional layer 600 facing away from the substrate 100.

Optionally, the optical device 710 overlaps with the photosensitive sensor 220, which may mean that the orthographic projection of the optical device 710 on the substrate 100 may at least partially overlap with the orthographic projection of the photosensitive sensor 220 on the substrate 100.

Optionally, a single optical device 710 may be provided corresponding to a single photosensitive sensor 220. For example, the orthographic projection of the single optical device 710 on the substrate 100 may at least partially overlap with the orthographic projection of the single photosensitive sensor 220 on the substrate 100.

Optionally, the photosensitive sensor 220 and the optical device 710 may form a light-sensing device in the display panel 10. The light-sensing device may comprise a color temperature sensor, a camera, or other light-sensing devices. For example, there may be multiple light-sensing channels ST in the display panel 10 that may form the light-sensing device in the display panel 10.

For ease of description, the following embodiments are described by taking the photosensitive device comprising a color temperature sensor as an example; that is, the following embodiments are described by taking the example that the photosensitive sensor 220 and the optical device 710 can be configured to sense the brightness and color temperature of ambient light.

The optical device 710 comprises a composite color-resist structure 711 and a basic color-resist structure 712. The composite color-resist structure 711 and the basic color-resist structure 712 can be configured to allow light of different wavelength ranges to pass through, so that the composite color-resist structure 711 and the basic color-resist structure 712 can be configured to form different photosensitive channels ST, respectively, to decompose ambient light into light in multiple wavelength ranges for sensing, thereby better improving the accuracy of the photosensitive operation of the display panel 10.

Optionally, the basic color-resist structure 712 comprises a first-type color-resist structure 712a and a second-type color-resist structure 712b. The first-type color-resist structure 712a allows light in a first wavelength range to pass through, and the second-type color-resist structure 712b allows light in a second wavelength range to pass through.

Optionally, the first wavelength range may not be exactly the same as the second wavelength range. In the embodiments of the present application, the term “a certain wavelength range is not exactly the same as another wavelength range” may mean that at least some wavelengths in a wavelength range may not be within the other wavelength range, and/or at least some wavelengths in the other wavelength range may not be within the one wavelength range.

For example, the first wavelength range and the second wavelength range may have an intersection, some wavelengths in the first wavelength range are not within the second wavelength range, and some wavelengths in the second wavelength range are not within the first wavelength range, so that the first-type color-resist structure 712a and the underlying photosensitive sensor 220 which the first-type color-resist structure 712a overlaps can constitute a first-type channel ST1, and the second-type color-resist structure 712b and the underlying photosensitive sensor 220 which the second-type color-resist structure 712b overlaps can constitute a second-type channel ST2. The first-type channel ST1 and the second-type channel ST2 can be configured to sense light in different wavelength ranges, thereby better improving the accuracy of the photosensitive operation of the display panel 10.

Optionally, there are various ways to set the first wavelength range and the second wavelength range. For example, the average value of the first wavelength range may be greater than the average value of the second wavelength range, or the average value of the first wavelength range may be less than the average value of the second wavelength range.

For ease of description, the following embodiments are described by taking the example that the average value of the first wavelength range is greater than the average value of the second wavelength range.

Optionally, the first wavelength range may be 450 nm-670 nm, and the second wavelength range may be 380 nm-560 nm. For example, the first-type color-resist structure 712a comprises a green color-resist material, and the second-type color-resist structure 712b comprises a blue color-resist material, so that the first-type channel ST1 can be primarily configured to sense green light, and the second-type channel ST2 can be primarily configured to sense blue light.

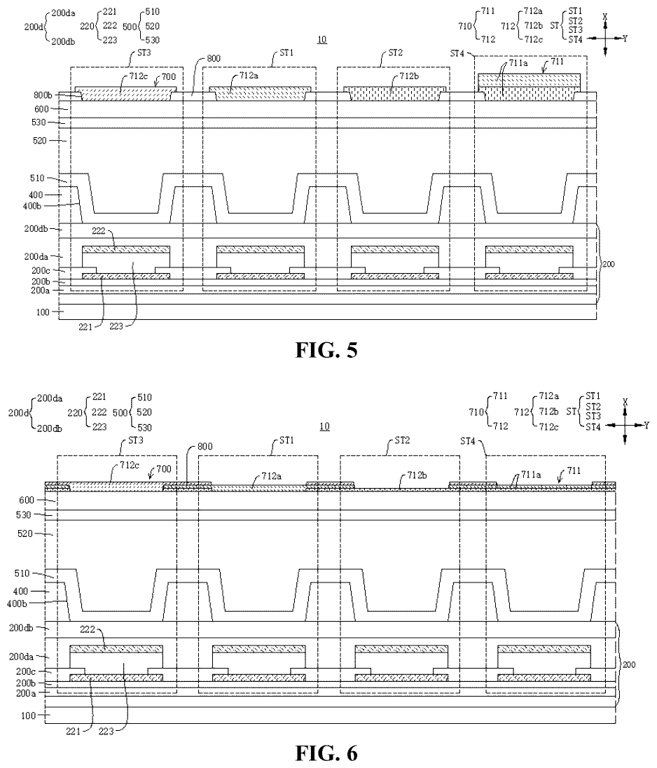

FIG. 5 is a partial cross-sectional view of a display panel 10 provided in yet another embodiment of the present application.

Optionally, as shown in FIG. 5, the basic color-resist structure 712 further comprises a third-type color-resist structure 712c allowing light in a third wavelength range to pass through.

Optionally, the third wavelength range may not be exactly the same as the first wavelength range or the second wavelength range, so that the third-type color-resist structure 712c and the underlying photosensitive sensor 220 which the third-type color-resist structure 712c overlaps may constitute a third-type channel ST3. The first-type channel ST1, the second-type channel ST2, and the third-type channel ST3 may be configured to sense light in different wavelength ranges, thereby better improving the accuracy of the photosensitive operation of the display panel 10.

Optionally, there are multiple ways to set the third wavelength range. For example, the average value of the third wavelength range is greater than the average value of the first wavelength range, or the average value of the third wavelength range may be less than the average value of the second wavelength range.

For ease of description, the following embodiments are described by taking the example that the average value of the third wavelength range is greater than the average value of the first wavelength range.

Optionally, the third wavelength range may be 580 nm-W nm, where W may be greater than 1000 nm. Exemplarily, the third-type color-resist structure 712c comprises a red color-resist material, so that the third-type channel ST3 may be primarily configured to sense red light.

Optionally, the wavelength range of light that can pass through the composite color-resist structure 711 may not be exactly the same as the wavelength range of light that can pass through any basic color-resist structure 712, so that the composite color-resist structure 711 and the underlying photosensitive sensor 220 which the composite color-resist structure 711 overlaps can form a composite channel ST4. The first-type channel ST1, the second-type channel ST2, the third-type channel ST3, and the composite channel ST4 can be configured to sense light in different wavelength ranges, thereby better improving the accuracy of the photosensitive operation of the display panel 10.

For example, the wavelength range of light that can pass through the composite color-resist structure 711 may not be exactly the same as the first wavelength range, the wavelength range of light that can pass through the composite color-resist structure 711 may not be exactly the same as the second wavelength range, and the wavelength range of light that can pass through the composite color-resist structure 711 may not be exactly the same as the third wavelength range.

Optionally, the color-resist layer 700 further comprises a color-resist device 720 provided on a side of the light-emitting unit 310 in the first direction X. The light-emitting unit 310 overlaps with the color-resist device 720 in the first direction X. The light emitted by the light-emitting unit 310 can be transmitted outward through the color-resist device 720, which is beneficial to improving the display effect of the display panel 10.

Optionally, the color-resist device 720 may be located in the display area AA.

Optionally, the light-emitting unit 310 overlaps with the color-resist device 720 in the first direction X, which may mean that the color-resist device 720 may overlap with the light-emitting structure 312b in the light-emitting unit 310 in the first direction X. For example, the orthographic projection of the color-resist device 720 on the substrate 100 may at least partially overlap with the orthographic projection of the light-emitting structure 312b on the substrate 100.

Optionally, a single color-resist device 720 may be provided corresponding to a single light-emitting unit 310. For example, the orthographic projection of a single color-resist device 720 on the substrate 100 may at least partially overlap with the orthographic projection of a single light-emitting structure 312b on the substrate 100.

Optionally, the color-resist device 720 comprises a red color-resist structure 721, a green color-resist structure 722, and a blue color-resist structure 723. The red color-resist structure 721 allows red light to pass through, the green color-resist structure 722 allows green light to pass through, and the blue color-resist structure 723 allows blue light to pass through. For example, the red color-resist structure 721 may overlap with the red light-emitting unit 310a in the first direction X, the green color-resist structure 722 may overlap with the green light-emitting unit 310b in the first direction X, and the blue color-resist structure 723 may overlap with the blue light-emitting unit 310c in the first direction X.

Optionally, the basic color-resist structure 712 can be made of the same material as at least part of the color-resist device 720, so that during the preparation process of the display panel 10, a part of the basic color-resist structure 712 and the corresponding color-resist device 720 can be prepared together. This can help reduce the cost of the display panel 10 and improve the preparation efficiency of the display panel 10.

Exemplarily, the first-type color-resist structure 712a may be made of the same material as the green color-resist structure 722, so that during the preparation process of the display panel 10, the first-type color-resist structure 712a and the green color-resist structure 722 can be prepared in the same preparation step using the same color-resist material. The second-type color-resist structure 712b may be made of the same material as the blue color-resist structure 723, so that during the preparation process of the display panel 10, the second-type color-resist structure 712b and the blue color-resist structure 723 can be prepared in the same preparation step using the same color-resist material. The third-type color-resist structure 712c may be made of the same material as the red color-resist structure 721, so that during the preparation process of the display panel 10, the third-type color-resist structure 712c and the red color-resist structure 721 can be prepared in the same preparation step using the same color-resist material.

Optionally, the display panel 10 further comprises a light-shielding layer 800 located on a side of the pixel layer away from the substrate 100. The light-shielding layer 800 can be configured to block light, which can help reduce reflection of ambient light and reduce crosstalk between different light rays in the display panel 10. For example, the light-shielding layer 800 can help reduce crosstalk between light passing through adjacent optical devices 710, and/or help reduce crosstalk between light passing through adjacent color-resist devices 720, and/or help reduce crosstalk between light passing through adjacent optical devices 710 and color-resist devices 720.

FIG. 6 is a partial cross-sectional view of a display panel 10 provided in yet another embodiment of the present application.

Optionally, to achieve the function of blocking light, the material of the light-shielding layer 800 can be set in a variety of ways. For example, as shown in FIGS. 2 to 5, the light-shielding layer 800 can be made of an opaque material, and the color-resist layer 700 is located on a side of the light-shielding layer 800 away from the substrate. Alternatively, as shown in FIG. 6, the light-shielding layer 800 can be formed by stacking at least two of the first color-resist material, the second color-resist material, or the third color-resist material in the first direction X.

Optionally, in the case that the light-shielding layer 800 is made of an opaque material, the color-resist layer 700 is located on the side of the light-shielding layer 800 away from the substrate. This means that during the preparation process of the display panel 10, the light-shielding layer 800 may be prepared first and then the color-resist layer 700 may be prepared.

Optionally, the filtering wavelength ranges of the first-type color-resist material, the second-type color-resist material, and the third-type color-resist material may be different from each other, so that the first-type color-resist material, the second-type color-resist material, and the third-type color-resist material stacked in the first direction X can block the transmission of light. For example, the first-type color-resist material may comprise a green color-resist material, the second-type color-resist material may comprise a blue color-resist material, and the third-type color-resist material may comprise a red color-resist material.

Optionally, the first-type color-resist material can be made of the same material as the first-type color-resist structure 712a on a circumferential side thereof and can be integrally formed, so that during the preparation process of the display panel 10, the first-type color-resist structure 712a and the first-type color-resist material can be prepared in the same preparation step using the same color-resist material. The second-type color-resist material can be made of the same material as the second-type color-resist structure 712b on a circumferential side thereof and can be integrally formed, so that during the preparation process of the display panel 10, the second-type color-resist structure 712b and the second-type color-resist material can be prepared in the same preparation step using the same color-resist material. The third-type color-resist material can be made of the same material as the third-type color-resist structure 712c on a circumferential side thereof and can be integrally formed, so that during the preparation process of the display panel 10, the third-type color-resist structure 712c and the third-type color-resist material can be prepared in the same preparation step using the same color-resist material.

For ease of description, the following embodiments are described by taking the light-shielding layer 800 as an example of an opaque material.

Optionally, as shown in FIGS. 2 to 5, a first opening 800a and a second opening 800b are provided on the light-shielding layer 800, the color-resist device 720 is located in the first opening 800a, and the optical device 710 is located in the second opening 800b, so that the arrangement of the light-shielding layer 800 helps reduce crosstalk between different light rays in the display panel 10.

Optionally, the first opening 800a may be at least partially located in the display area AA.

Optionally, a part of the material of the color-resist device 720 and a part of the material of the optical device 710 may extend to the side of the light-shielding layer 800 facing away from the substrate 100. That is, the color-resist device 720 may be partially located in the first opening 800a and partially extend to the side of the light-shielding layer 800 facing away from the substrate 100, and the optical device 710 may be partially located in the second opening 800b and partially extend to the side of the light-shielding layer 800 facing away from the substrate 100.

Optionally, the display panel 10 further comprises a pixel defining layer 400, which can be configured to divide the sub-pixels of the display panel 10. Exemplarily, the pixel defining layer 400 is provided with a third opening 400a. In the first direction X, the first opening 800a overlaps with the third opening 400a, and the light-emitting unit 310 can be partially located within the third opening 400a.

Optionally, the third opening 400a may be at least partially located in the display area AA.

Optionally, the light-emitting unit 310 may be partially located within the third opening 400a, which may mean that in the light-emitting unit 310, the light-emitting functional layer 312 and the second electrode 313 may be partially located within the third opening 400a. The pixel defining layer 400 may be provided on the side of the first electrode 311 away from the substrate 100, and a part of the surface of the first electrode 311 away from the substrate 100 may be exposed from the third opening 400a and connected to the light-emitting functional layer 312 within the third opening 400a, so that the first electrode 311 participates in driving the light-emitting functional layer 312 to emit light.

Optionally, the pixel defining layer 400 may further comprise a fourth opening 400b, and the second opening 800b overlaps with the fourth opening 400b along the first direction X. By providing the fourth opening 400b overlapping with the second opening 800b, ambient light can better pass through the second opening 800b and the fourth opening 400b to illuminate the photosensitive sensor 220, thereby reducing the shielding effect of light by the pixel defining layer 400.

Optionally, the pixel defining layer 400 may be made of an opaque material, which can help reduce reflection of ambient light and reduce crosstalk between different light rays in the display panel 10. For example, the pixel defining layer 400 can help reduce crosstalk between light rays passing through adjacent optical devices 710, and/or help reduce crosstalk between light rays passing through adjacent color-resist devices 720, and/or help reduce crosstalk between light rays passing through adjacent optical devices 710 and color-resist devices 720.

Optionally, the size of the first opening 800a may be larger than the size of the third opening 400a, so that light emitted from the first opening 800a can be emitted outward from the third opening 400a in a more divergent manner. This means that the light-shielding layer 800 is less likely to significantly block the light emitted by the light-emitting unit 310, thereby effectively improving the display effect of the display panel 10. For example, the area of the first opening 800a may be larger than the area of the third opening 400a. This means that the area of the first opening 800a may refer to the area of the orthographic projection of the first opening 800a on the substrate 100, and the area of the third opening 400a may refer to the area of the orthographic projection of the third opening 400a on the substrate 100.

Optionally, the orthographic projection of the third opening 400a on the substrate 100 may be located within the orthographic projection of the first opening 800a on the substrate 100.

Optionally, the size of the second opening 800b may be larger than or equal to the size of the fourth opening 400b. This ensures that the second opening 800b is less likely to have an excessively small size, allowing sufficient light to pass through the optical device 710. It also ensures that the fourth opening 400b is less likely to have an excessively large size, thereby reducing the space occupied by the fourth opening 400b in the display panel 10 and reducing crosstalk between light rays. For example, the area of the second opening 800b is larger than or equal to the area of the fourth opening 400b. The area of the second opening 800b may refer to the area of the orthographic projection of the second opening 800b on the substrate 100, and the area of the fourth opening 400b may refer to the area of the orthographic projection of the fourth opening 400b on the substrate 100.

Optionally, the orthographic projection of the fourth opening 400b on the substrate 100 may overlap with the orthographic projection of the second opening 800b on the substrate 100.

Optionally, the size of the first opening 800a may be larger than the size of the second opening 800b. This ensures that the first opening 800a is likely to have a larger size, and the light emitted from the first opening 800a can be emitted outward from the third opening 400a in a more divergent manner, which can effectively improve the display effect of the display panel 10. This also ensures that the second opening 800b is likely to have a smaller size, so that the optical device 710 is less likely to occupy a larger area of the display panel 10. For example, the area of the first opening 800a can be larger than the area of the second opening 800b.

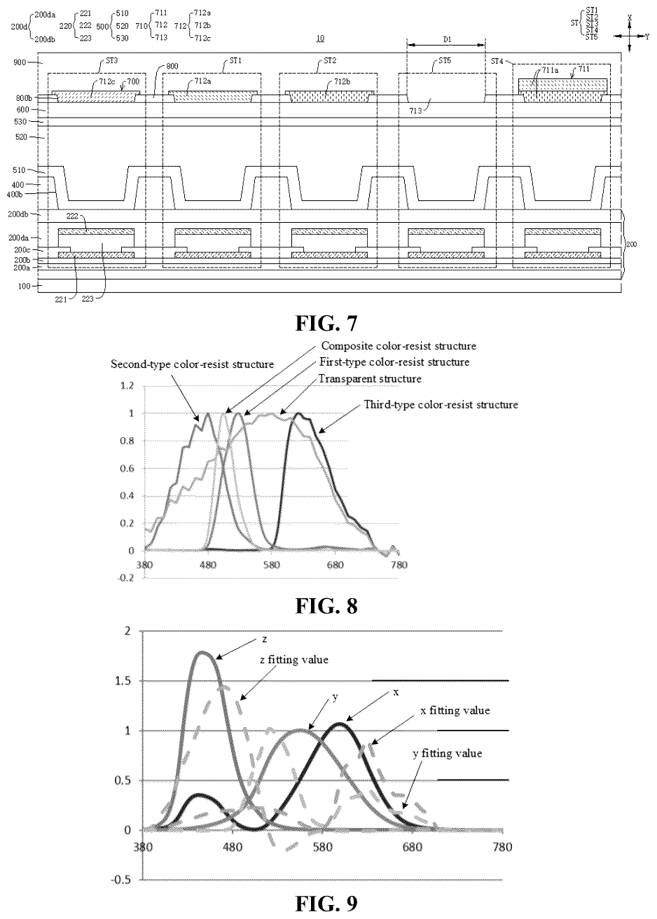

FIG. 7 is a partial cross-sectional view of a display panel 10 provided in another embodiment of the present application.

As shown in FIG. 7, optionally, the optical device 710 further comprises a transparent structure 713, which allows visible light to pass through, so that the wavelength range of light that can pass through the transparent structure 713 may not be exactly the same as the wavelength range of light that can pass through any basic color-resist structure 712, and the wavelength range of light that can pass through the transparent structure 713 may not be exactly the same as the wavelength range of light that can pass through the composite color-resist structure 711. Therefore, the transparent structure 713 and the underlying photosensitive sensor 220 which the transparent structure 713 overlaps can constitute a transparent channel ST5. The first-type channel ST1, the second-type channel ST2, the third-type channel ST3, the composite channel ST4, and the transparent channel ST5 can be configured to sense light in different wavelength ranges, thereby greatly improving the accuracy of the photosensitive operation of the display panel 10.

Optionally, the display panel 10 further comprises an optically transparent adhesive layer 900 provided on a side of the composite color-resist structure 711 facing away from the photosensitive sensor 220 and a side of the basic color-resist structure 712 facing away from the photosensitive sensor 220. The optically transparent adhesive layer 900 can be configured to protect the color-resist layer 700. Exemplarily, the optically transparent adhesive layer 900 may comprise optical clear adhesive.

Optionally, the transparent structure 713 may be made of the same material as the optically transparent adhesive layer 900. For example, the transparent structure 713 may be integrally formed with the optically transparent adhesive layer 900. This allows the transparent structure 713 to be formed simultaneously with the optically transparent adhesive layer 900 during the production of the display panel 10. This eliminates the need for additional preparation steps for the transparent structure 713 to be separately prepared, thereby improving the production efficiency of the display panel 10. For example, the optically transparent adhesive layer 900 that falls into the second opening 800b may be reused as the transparent structure 713.

Optionally, the sizes of the second openings 800b for accommodating different optical devices 710 may be the same or different.

Optionally, to facilitate the arrangement of the optical device 710, the sizes of the second openings 800b may be the same. Exemplarily, the areas of the second openings 800b are all equal.

Optionally, the second opening 800b may have a first size in the second direction Y and/or the third direction Z (D1 in FIG. 7 may indicate the first size). The first size may be no less than 12 μm and no greater than 18 μm. For example, the first size may be 15 μm. By properly setting the size of the second opening 800b, the optical device 710 is less likely to occupy a larger area of the display panel 10, while the light passing through the optical device 710 is sufficient.

By configuring the composite color-resist structure 711 to comprise at least two sub-color-resist structures 711a stacked in the first direction X and having different filtering wavelength ranges, the intersection of the filtering wavelength ranges of the stacked sub-color-resist structures 711a can be the filtering wavelength range of the composite color-resist structure 711. Furthermore, the filtering wavelength range of the composite color-resist structure 711 may be different from the filtering wavelength ranges of the sub-color-resist structures 711a. This allows the photosensitive channel ST formed by the composite color-resist structure 711 and the photosensitive sensor 220 below the composite color-resist structure 711 to be distinguishable from the photosensitive channels ST formed by the sub-color-resist structures 711a.

Optionally, the filtering wavelength range of a color-resist described in the embodiments of the present application may refer to the wavelength range of light that can pass through the color-resist. For example, the filtering wavelength range of the sub-color-resist structure 711a may refer to the wavelength range of light that can pass through the sub-color-resist structure 711a.

Optionally, the filtering wavelength ranges of each sub-color-resist structure 711a in the composite color-resist structure 711 may have an intersection, so that light within at least a part of the wavelength range can pass through the composite color-resist structure 711 to the photosensitive sensor 220 in the composite channel ST4.

Optionally, in the sub-color-resist structures 711a with different filtering wavelength ranges in the composite color-resist structure 711, the materials of the sub-color-resists may also be different.

Optionally, the number of sub-color-resist structures 711a in a single composite color-resist structure 711 may be set in various ways. For example, a single composite color-resist structure 711 may comprise two sub-color-resist structures 711a stacked in the first direction X, or a single composite color-resist structure 711 may comprise more than two sub-color-resist structures 711a stacked in the first direction X. In the case that the number of sub-color-resist structures 711a in the composite color-resist structure 711 is greater, light needs to pass through more sub-color-resist structures 711a to penetrate the composite color-resist structure 711, resulting in a narrower wavelength range of light that can pass through the composite color-resist structure 711.

For ease of description, the following embodiments are described by taking an example that one composite color-resist structure 711 may comprise two sub-color-resist structures 711a stacked in the first direction X.

By setting at least one sub-color-resist structure 711a to be made of the same material as at least one basic color-resist structure 712, during the preparation process of the display panel 10, at least one same color-resist material can be used to prepare one basic color-resist structure 712 and one sub-color-resist structure 711a in the composite color-resist structure 711. In this way, while using the composite color-resist structure 711, which is different from the basic color-resist structure 712, to form a new photosensitive channel ST, the accuracy of the photosensitive operation of the display panel 10 can be improved, and the preparation of the composite color-resist structure 711 can be facilitated, thereby facilitating the preparation of the display panel 10.

As an example, in the composite color-resist structure 711, the material of a part of the sub-color-resist structures 711a may be the same as the material of the corresponding basic color-resist structure 712, and the material of another part of the sub-color-resist structures 711a may be different from the material of any basic color-resist structure 712. That is, during the preparation process of the display panel 10, the preparation of a part of the sub-color-resist structures 711a and the corresponding basic color-resist structure 712 can be completed in the same preparation step using the same color-resist material, while the preparation of another part of the sub-color-resist structures 711a can be completed using a material different from the basic color-resist structure 712, so that the overall filtering wavelength range of the composite color-resist structure 711 can be adjusted by adjusting the material of the sub-color-resist structure 711a that is different from the basic color-resist structure 712, thereby better adjusting the accuracy of the photosensitive operation of the display panel 10.

As another example, in the composite color-resist structure 711, the material of each sub-color-resist structure 711a can be the same as the material of the corresponding basic color-resist structure 712, so that during the preparation process of the display panel 10, when the preparation of each basic color-resist structure 712 is gradually completed, the preparation of each sub-color-resist structure 711a in the composite color-resist structure 711 can be gradually completed at the same time, so that there is no need to add new preparation steps to separately prepare a part of sub-color-resist structures 711a, which can help reduce the cost of the display panel 10 and improve the preparation efficiency of the display panel 10.

For ease of description, the following embodiments are described by taking as an example that the material of each sub-color-resist structure 711a is the same as the material of the corresponding basic color-resist structure 712.

In some embodiments of the present application, there are various ways to set the material correspondence between the sub-color-resist structures 711a and the basic color-resist structures 712. Alternatively, each sub-color-resist structure 711a in the composite color-resist structure 711 may be prepared using materials of at least two basic color-resist structures 712 that have a significant intersection in their filtering wavelength ranges, thereby allowing light that can pass through the composite color-resist structure 711 to have a wider wavelength range.

For example, in the case that the basic color-resist structure 712 comprises a first-type color-resist structure 712a, a second-type color-resist structure 712b, and a third-type color-resist structure 712c, and the first wavelength range, the second wavelength range, and the third wavelength range are 450 nm-670 nm, 380 nm-560 nm, and 580 nm-W nm, respectively, the sub-color-resist structures 711a in the composite color-resist structure 711 may be prepared using the materials of which the first-type color-resist structure 712a and the second-type color-resist structure 712b are made, which have a significant intersection in the filtering wavelength ranges.

In some optional embodiments, at least one sub-color-resist structure 711a is made of the same material as the first-type color-resist structure 712a, and at least one sub-color-resist structure 711a is made of the same material as the second-type color-resist structure 712b.

For example, the composite color-resist structure 711 may comprise two sub-color-resist structures 711a. In the composite color-resist structure 711, one sub-color-resist structure 711a is made of the same material as the first-type color-resist structure 712a, and the other sub-color-resist structure 711a is made of the same material as the second-type color-resist structure 712b.

Optionally, the composite color-resist structure 711 allows light with a wavelength range of 450 nm-560 nm to pass through.

In these optional embodiments, by setting at least one sub-color-resist structure 711a in the composite color-resist structure 711 to be made of the same material as the first-type color-resist structure 712a, and by setting at least one sub-color-resist structure 711a in the composite color-resist structure 711 to be made of the same material as the second-type color-resist structure 712b, when preparing the first-type color-resist structure 712a, the first-type color-resist structure 712a and the sub-color-resist structure 711a corresponding to the first-type color-resist structure 712a in the composite color-resist structure 711 can be simultaneously prepared using the same material, and when preparing the second-type color-resist structure 712b, the second-type color-resist structure 712b and the sub-color-resist structure 711a corresponding to the second-type color-resist structure 712b in the composite color-resist structure 711 can be simultaneously prepared using the same material, thereby reducing the cost of the display panel 10 and improving the preparation efficiency of the display panel 10.

As an example, when the photosensitive channel ST comprises a first-type channel ST1, a second-type channel ST2, a third-type channel ST3, a composite channel ST4 and a transparent channel ST5, the following formula can be used to fit the color matching function according to the electrical signal of the photosensitive sensor 220 in each photosensitive channel ST.

$$[ \begin{matrix}\overline{x} \\ \overline{y} \\ \overline{z}\end{matrix} ] = [ \begin{matrix}a & b & c & d & e \\ f & g & h & i & j \\ k & l & m & n & o\end{matrix} ] [ \begin{matrix}R \\ G \\ B \\ C \\ H\end{matrix} ]$$

In the formula, R, G, B, C, and H may be the electrical signal values of the photosensitive sensor 220 of the first-type channel ST1, the electrical signal value of the photosensitive sensor 220 of the second-type channel ST2, the electrical signal value of the photosensitive sensor 220 of the third-type channel ST3, the electrical signal value of the photosensitive sensor 220 of the transparent channel ST5, and the electrical signal value of the photosensitive sensor 220 of the composite channel ST4, respectively, where a-o in the formula may be parameters in the fitting formula.

FIG. 8 is a normalized transmittance spectrum of each optical device 710 provided in an embodiment of the present application.

As an example, in the case that the first wavelength range, the second wavelength range, and the third wavelength range are 450 nm-670 nm, 380 nm-560 nm, and 580 nm-Wnm, respectively, and the composite color-resist structure 711 can allow light in the wavelength range of 450 nm-560 nm to pass through, and the transparent structure 713 can allow light in at least the visible light range to pass through, the normalized transmittance spectra of the first color-resist structure 712a, the second color-resist structure 712b, the third color-resist structure 712c, the composite color-resist structure 711, and the transparent structure 713 can be shown in FIG. 8. The abscissa in FIG. 8 represents wavelength, and the ordinate represents normalized transmittance. As can be seen from FIG. 8, different optical devices 710 have different transmittances for light of different wavelengths. By properly adjusting the filtering wavelength range of each optical device 710, the accuracy of the photosensitive operation of the display panel 10 can be better adjusted.

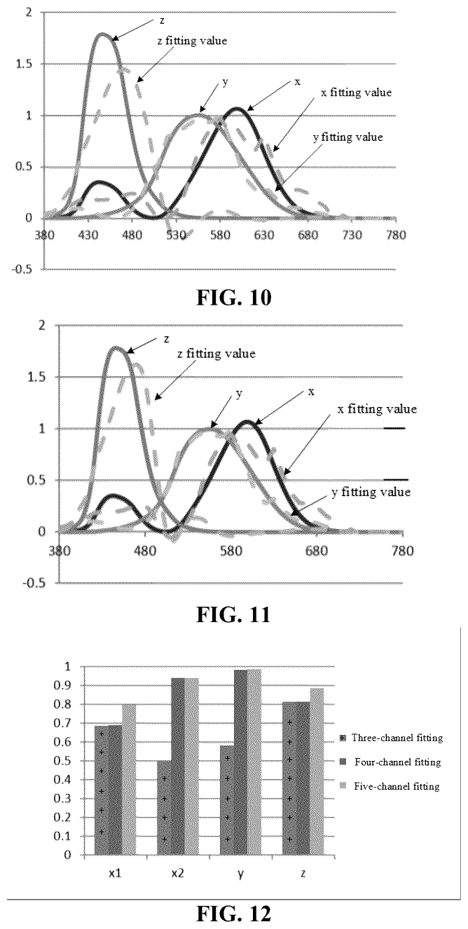

FIG. 9 is a schematic diagram of a color matching function obtained by fitting the first-type channel ST1, the second-type channel ST2, and the third-type channel ST3 provided in an embodiment of the present application. FIG. 10 is a schematic diagram of a color matching function obtained by fitting the first-type channel ST1, the second-type channel ST2, the third-type channel ST3, and the transparent channel ST5 provided in an embodiment of the present application. FIG. 11 is a schematic diagram of a color matching function obtained by fitting the first-type channel ST1, the second-type channel ST2, the third-type channel ST3, the composite channel ST4, and the transparent channel ST5 provided in an embodiment of the present application. FIG. 12 is a schematic diagram of the fitting coefficients of the color matching function obtained by fitting the data of the photosensitive channels ST provided in an embodiment of the present application.

The abscissa in FIGS. 9 to 11 represents the wavelength, the ordinate represents the value of the color matching function, the red solid line represents the CIE color matching function x spectrum, the red dotted line represents the fitted color matching function x spectrum, the green solid line represents the CIE color matching function y spectrum, the green dotted line represents the fitted color matching function y spectrum, the blue solid line represents the CIE color matching function z spectrum, and the blue dotted line represents the fitted color matching function z spectrum.

The abscissa in FIG. 12 represents x, y, and z in the color matching function, and the ordinate represents the fitting coefficient. When the fitting coefficient is closer to 1, the accuracy of the fitted color matching function is higher. Since the color matching function x spectrum is bimodal, x is split into x1 (wavelength range: 380 nm-500 nm) and x2 (wavelength range: 500 nm-780 nm) in FIG. 12. The three-channel fitting in FIG. 12 refers to the fitting coefficients obtained by fitting the color matching function using the first-type channel ST1, the second-type channel ST2, and the third-type channel ST3. The four-channel fitting in FIG. 12 refers to the fitting coefficients obtained by fitting the color matching function using the first-type channel ST1, the second-type channel ST2, the third-type channel ST3, and the transparent channel ST5. The five-channel fitting in FIG. 12 refers to the fitting coefficients obtained by fitting the color matching function using the first-type channel ST1, the second-type channel ST2, the third-type channel ST3, the composite channel ST4, and the transparent channel ST5.

As shown in FIGS. 9 to 12, as the number of photosensitive channels ST increases, the error between the fitted color matching function and the CIE color matching function becomes smaller and smaller. In other words, as the number of photosensitive channels ST increases, the accuracy of the light sensing operation of the display panel 10 becomes higher and higher. For example, when the photosensitive channels ST in the display panel 10 are configured to sense the color temperature of ambient light, since the accuracy of the fitted color matching function determines the accuracy of color temperature sensing, as the number of photosensitive channels ST increases, it is beneficial to improve the accuracy of the fitted color matching function, thereby better improving the accuracy of the display panel 10 in sensing color temperature.

Therefore, in the embodiments of the present application, by adding a composite color-resist structure 711 and reasonably arranging the structure of the composite color-resist, the composite color-resist structure 711 that is different from the basic color-resist structure 712 is used to form a new photosensitive channel ST, thereby improving the accuracy of the color temperature sensing operation of the display panel 10, facilitating the preparation of the composite color-resist structure 711, and thus facilitating the preparation of the display panel 10.

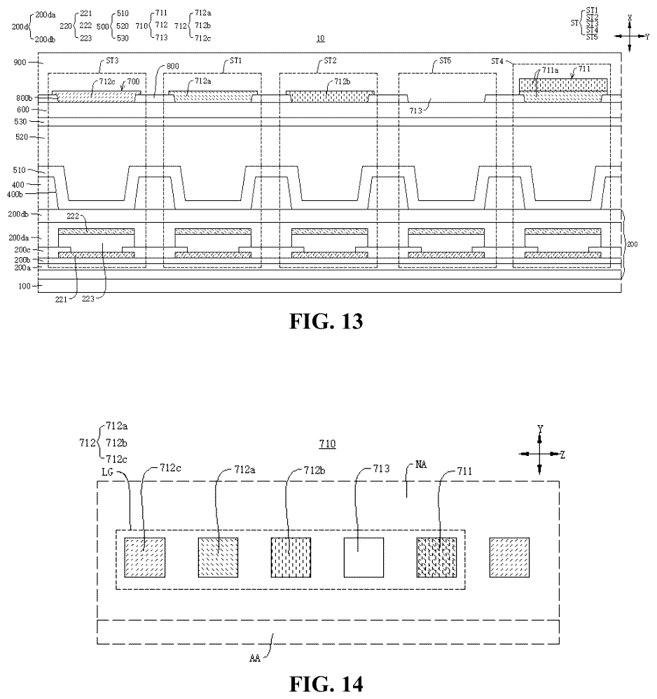

FIG. 13 is a partial cross-sectional view of a display panel 10 provided in another embodiment of the present application.

In some embodiments of the present application, the stacking positions of the sub-color-resist structures 711a made of different materials can be in various ways. For example, in the case that at least one sub-color-resist structure 711a is made of the same material as the first-type color-resist structure 712a, and at least one sub-color-resist structure 711a is made of the same material as the second-type color-resist structure 712b, the sub-color-resist structure 711a made of the same material as the first-type color-resist structure 712a can be provided on the side of the sub-color-resist structure 711a made of the same material as the second-type color-resist structure 712b facing away from the photosensitive sensor 220 (as shown in FIG. 7), or the sub-color-resist structure 711a made of the same material as the first-type color-resist structure 712a can be provided on the side of the sub-color-resist structure 711a made of the same material as the second-type color-resist structure 712b close to the photosensitive sensor 220 (as shown in FIG. 13).

In some embodiments, since at least one sub-color-resist structure 711a is made of the same material as at least one basic color-resist structure 712, the at least one sub-color-resist structure 711a can be prepared in the same preparation step as the basic color-resist structure 712. Therefore, the stacking positional relationship between the corresponding sub-color-resist structures 711a made of different materials can be formed based on the preparation sequence of the basic color-resist structure 712.

As an example, in the case that at least one sub-color-resist structure 711a is made of the same material as the first-type color-resist structure 712a, and at least one sub-color-resist structure 711a is made of the same material as the second-type color-resist structure 712b, if the preparation step of the second-type color-resist structure 712b in the basic color-resist structure 712 is performed before the preparation step of the first-type color-resist structure 712a, as shown in FIG. 7, the material of the sub-color-resist structure 711a made of the same material as the second-type color-resist structure 712b can be formed before the material of the sub-color-resist structure 711a made of the same material as the first-type color-resist structure 712a is formed, so that the sub-color-resist structure 711a made of the same material as the first-type color-resist structure 712a can be provided on the side of the sub-color-resist structure 711a made of the same material as the second-type color-resist structure 712b away from the photosensitive sensor 220.

As another example, in the case that at least one sub-color-resist structure 711a is made of the same material as the first-type color-resist structure 712a, and at least one sub-color-resist structure 711a is made of the same material as the second-type color-resist structure 712b, if the preparation step of the second-type color-resist structure 712b in the basic color-resist structure 712 is performed after the preparation step of the first-type color-resist structure 712a, then as shown in FIG. 13, the material of the sub-color-resist structure 711a made of the same material as the second-type color-resist structure 712b can be formed after the material of the sub-color-resist structure 711a made of the same material as the first-type color-resist structure 712a is formed, so that the sub-color-resist structure 711a made of the same material as the first-type color-resist structure 712a can be provided on the side of the sub-color-resist structure 711a made of the same material as the second-type color-resist structure 712b close to the photosensitive sensor 220.

In these embodiments, the preparation sequence of the basic color-resist structure 712 may be the same as the preparation sequence of the corresponding color-resist device 720.

For example, in the case that the first-type color-resist structure 712a is made of the same material as the green color-resist structure 722, the second-type color-resist structure 712b is made of the same material as the blue color-resist structure 723, and the third-type color-resist structure 712c is made of the same material as the red color-resist structure 721, the preparation of the first-type color-resist structure 712a and the green color-resist structure 722 can be completed in the same preparation step, the preparation of the second-type color-resist structure 712b and the blue color-resist structure 723 can be completed in the same preparation step, and the preparation of the third-type color-resist structure 712c and the red color-resist structure 721 can be completed in the same preparation step.

Therefore, if during the preparation process of the color-resist device 720, the blue color-resist structure 723, the green color-resist structure 722, and the red color-resist structure 721 are prepared in sequence, the second-type color-resist structure 712b, the first-type color-resist structure 712a, and the third-type color-resist structure 712c are prepared in sequence. If during the preparation process of the color-resist device 720, the red color-resist structure 721, the green color-resist structure 722, and the blue color-resist structure 723 are prepared in sequence, the third-type color-resist structure 712c, the first-type color-resist structure 712a, and the second-type color-resist structure 712b are prepared in sequence.

In some optional embodiments, the first-type color-resist structure 712a, the second-type color-resist structure 712b, the third-type color-resist structure 712c, the composite color-resist structure 711, and the transparent structure 713 form an optical device group LG, and there are multiple optical device groups LG.

Optionally, there are various ways to set the number of the first-type color-resist structure 712a, the second-type color-resist structure 712b, the third-type color-resist structure 712c, the composite color-resist structure 711, and the transparent structure 713 in the optical device group LG. For example, a single first-type color-resist structure 712a, a single second-type color-resist structure 712b, a single third-type color-resist structure 712c, a single composite color-resist structure 711, and a single transparent structure 713 may form one optical device group LG, or the number of at least one of the first-type color-resist structure 712a, the second-type color-resist structure 712b, the third-type color-resist structure 712c, the composite color-resist structure 711, or the transparent structure 713 in one optical device group LG may be greater than two.

Optionally, the relative positional relationships of the optical devices 710 within the optical device group LG can be provided in a variety of ways. As an example, the optical devices 710 within a single optical device group LG can be provided adjacent to each other. For example, the optical devices 710 within a single optical device group LG can be provided side by side in the second direction Y or the third direction Z. As another example, the optical devices 710 within a single optical device group LG can be dispersed. For example, the optical devices 710 within the optical device group LG may not be provided in the same row or the same column, and may be provided in staggered rows in the second direction Y or staggered columns in the third direction Z. For ease of description, the following embodiments are described using the example in which the optical devices 710 within a single optical device group LG are disposed adjacent to each other.

In these optional embodiments, the first-type color-resist structure 712a, the second-type color-resist structure 712b, the third-type color-resist structure 712c, the composite color-resist structure 711, and the transparent structure 713 in the optical device group LG can form the first-type channel ST1, the second-type channel ST2, the third-type channel ST3, the composite channel ST4, and the transparent channel ST5 respectively. That is, the optical device group LG can effectively decompose ambient light into light of multiple wavelength ranges, thereby facilitating sensing of light of different wavelength ranges by different photosensitive sensors 220. By providing multiple optical device groups LG, the sensing results of the photosensitive sensors 220 corresponding to different optical device groups LG can be cross-referenced against each other, which can help improve the accuracy of the light sensing operation of the display panel 10.

In the embodiments of the present application, there are various ways to position and arrange the optical device group LG.

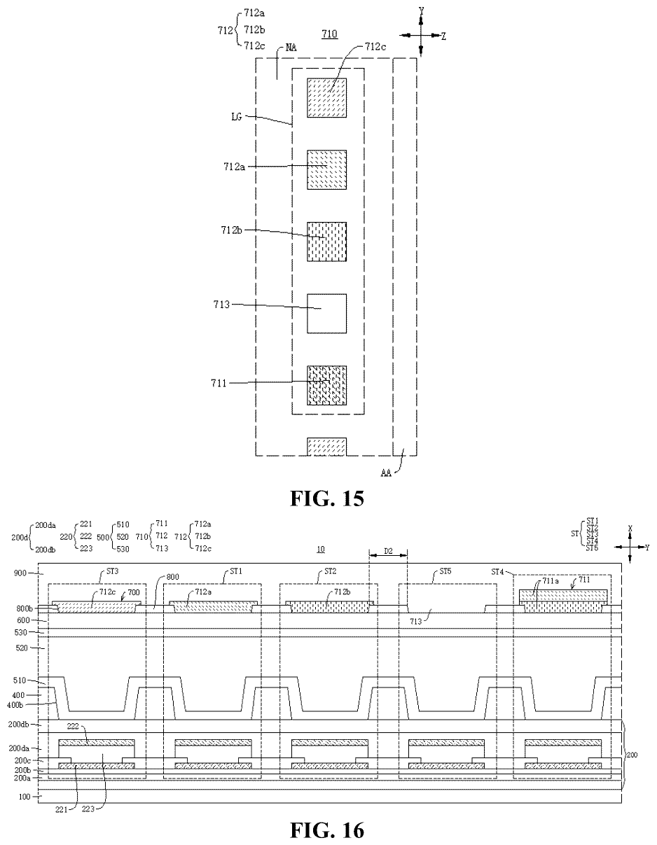

FIG. 14 is a partial structural diagram of an optical device 710 provided in an embodiment of the present application, and FIG. 15 is a schematic partial structural diagram of an optical device 710 provided in another embodiment of the present application. For example, FIG. 14 may be a partial schematic structural diagram of the optical device 710 at position J in FIG. 1 provided in some embodiments of the present application, and FIG. 15 may be a partial schematic structural diagram of the optical device 710 at position K in FIG. 1 provided in some embodiments of the present application.

In some embodiments, as shown in FIGS. 14 and 15, the optical device group LG can be provided in the non-display area NA, so that the arrangement of the optical device 710 and the photosensitive sensor 220 is less likely to affect the arrangement of the light-emitting unit 310, the color-resist device 720 and the pixel circuit 210 in the display area AA, which can facilitate the arrangement of a larger number of pixel units in the display area AA, thereby facilitating the improvement of the pixel density (Pixels Per Inch, PPI) of the display panel 10, and also allowing the arrangement of the larger-sized optical devices 710 and the photosensitive sensors 220 in the non-display area NA to improve the photosensitive effect of the display panel 10.

Optionally, the non-display area NA may be provided around the display area AA, and the optical device 710 and the photosensitive sensor 220 may be provided within the non-display area NA at any position on a circumferential side of the display area AA. For example, as shown in FIG. 14, at least a part of the optical device 710 and at least a part of the photosensitive sensor 220 may be provided within the non-display area NA located on at least one side of the display area AA in the second direction Y, that is, at least a part of the optical device 710 and at least a part of the photosensitive sensor 220 may be located on at least one side of the display area AA in the second direction Y. For another example, as shown in FIG. 15, at least a part of the optical devices 710 and at least a part of the photosensitive sensors 220 may be provided within the non-display area NA located on at least one side of the display area AA in the third direction Z, that is, at least a part of the optical devices 710 and at least a part of the photosensitive sensors 220 may be located on at least one side of the display area AA in the third direction Z.

Optionally, as shown in FIG. 14, the optical device group LG is located on at least one side of the display area AA in the second direction Y, and at least two optical device groups LG are provided side by side in the third direction Z. Specifically, the optical device groups LG are located on at least one side of the display area AA in the second direction Y, and the at least two optical device groups LG located on at least one side of the display area AA in the second direction Y may be provided side by side in the third direction Z. Exemplarily, the optical device groups LG located on at least one side of the display area AA in the second direction Y may be provided side by side in the third direction Z.

The optical devices 710 located on at least one side of the display area AA in the second direction Y are arranged in the third direction Z. The arrangement of the optical device group LG is less likely to excessively increase the size of the non-display area NA located on both sides of the display area AA in the second direction Y, that is, the non-display area NA located on both sides of the display area AA in the second direction Y is less likely to have an excessively large size in the second direction Y, thereby facilitating reduction of the bezel size of the display panel 10.

Similarly, as shown in FIG. 15, in the case that the optical device groups LG are located on at least one side of the display area AA in the third direction Z, the at least two optical device groups LG located on at least one side of the display area AA in the third direction Z may be provided side by side in the second direction Y. Exemplarily, the at least two optical device groups LG located on at least one side of the display area AA in the third direction Z may both be provided side by side in the second direction Y.

The optical devices 710 located on at least one side of the display area AA in the third direction Z are arranged in the second direction Y, the arrangement of the optical device groups LG are less likely to excessively increase the size of the non-display area NA located on both sides of the display area AA in the third direction Z, that is, the non-display area NA located on both sides of the display area AA in the third direction Z is less likely to have an excessively large size in the third direction Z, thereby facilitating reduction of the bezel size of the display panel 10.

Optionally, at least two optical devices 710 in the optical device group LG are provided side by side in the third direction Z. Exemplarily, as shown in FIG. 14, at least two optical devices 710 in the optical device group LG located on at least one side of the display area AA in the second direction Y are provided side by side in the third direction Z, so that the arrangement of the optical devices 710 is less likely to excessively increase the size of the non-display areas NA located on both sides of the display area AA in the second direction Y, that is, the non-display areas NA located on both sides of the display area AA in the second direction Y are less likely to have an excessively large size in the second direction Y.

Optionally, at least two optical devices 710 in the optical device group LG are provided side by side in the second direction Y. Exemplarily, as shown in FIG. 15, at least two optical devices 710 in the optical device group LG located on at least one side of the display area AA in the third direction Z are provided side by side in the second direction Y, so that the arrangement of the optical devices 710 is less likely to excessively increase the size of the non-display areas NA located on both sides of the display area AA in the third direction Z, that is, the non-display areas NA located on both sides of the display area AA in the third direction Z are less likely to have an excessively large size in the third direction Z.

FIG. 16 is a partial cross-sectional view of a display panel 10 provided in another embodiment of the present application.

As shown in FIG. 16, optionally, in the case that the optical device group LG is provided in the non-display area NA, the crosstalk of light between adjacent photosensitive channels ST can be reduced by properly setting the spacing between the optical devices 710, thereby effectively improving the accuracy of the light sensing operation of the display panel 10. For example, the crosstalk of light between adjacent photosensitive channels ST can be reduced by properly setting the spacing between the second openings 800b (D2 in FIG. 16 illustrates the spacing between adjacent second openings 800b).

Optionally, the distance between adjacent second openings 800b is greater than or equal to 45 μm, so that adjacent photosensitive channels ST can have a more proper spacing therebetween to reduce the crosstalk of light rays between adjacent photosensitive channels ST.

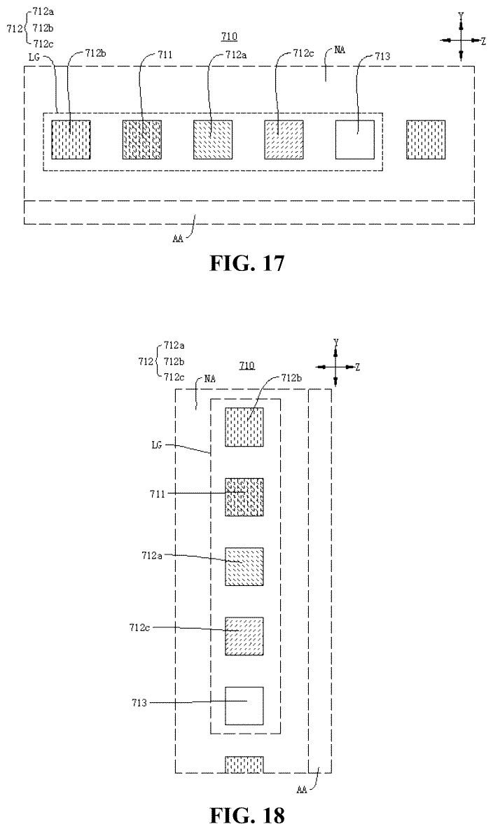

FIG. 17 is a partial schematic structural diagram of an optical device 710 provided in yet another embodiment of the present application, and FIG. 18 is a partial schematic structural diagram of an optical device 710 provided in yet another embodiment of the present application. For example, FIG. 17 may be a partial schematic structural diagram of the optical device 710 at position J in FIG. 1 provided in other embodiments of the present application, and FIG. 18 may be a partial schematic structural diagram of the optical device 710 at position K in FIG. 1 provided in other embodiments of the present application.

As shown in FIGS. 17 and 18, optionally, the relative position relationship between different types of optical devices 710 can be reasonably set to reduce the crosstalk of light rays between adjacent photosensitive channels ST, thereby improving the accuracy of the photosensitive operation of the display panel 10.

For example, the composite color-resist structure 711 can be provided between the first-type color-resist structure 712a and the second-type color-resist structure 712b, so that there is a larger gap between the first-type color-resist structure 712a and the second-type color-resist structure 712b and crosstalk is less likely to be generated between the first-type channel ST1 and the second-type channel ST2, which have a larger difference in the average values of their filtering wavelength ranges. Furthermore, since the wavelength range of light that can pass through the composite color-resist structure 711 may be the intersection of the first wavelength range and the second wavelength range, light that passes through the second openings 800b corresponding to the first-type channel ST1 and the second-type channel ST2 is less likely to excessively affect the photosensitive operation of the composite channel ST4, thereby better improving the accuracy of the photosensitive operation of the display panel 10.

For example, the first-type color-resist structure 712a is provided between the third-type color-resist structure 712c and the composite color-resist structure 711, so that there is a larger gap between the third-type color-resist structure 712c and the composite color-resist structure 711, and crosstalk is less likely to be generated between the third-type channel ST3 and the composite channel ST4, which have a larger difference in the average values of their filtering wavelength ranges. Furthermore, since the average value of the filtering wavelength range of the first-type color-resist structure 712a is closer to the average value of the filtering wavelength range of the third-type color-resist structure 712c than that of the composite color-resist structure 711, the impact of light passing through the second opening 800b corresponding to the third-type channel ST3 on the composite channel ST4 is smaller than the impact of light passing through the second opening 800b corresponding to the third-type channel ST3 on the first-type channel ST1, thereby better improving the accuracy of the light sensing operation of the display panel 10.

As an example, in the optical device group LG, the second-type color-resist structure 712b, the composite color-resist structure 711, the first-type color-resist structure 712a, the third-type color-resist structure 712c, and the transparent structure 713 are sequentially provided in the second direction Y or the third direction Z. Specifically, in the optical device group LG located on at least one side of the display area AA in the second direction Y, the second-type color-resist structure 712b, the composite color-resist structure 711, the first-type color-resist structure 712a, the third-type color-resist structure 712c, and the transparent structure 713 may be sequentially provided in the third direction Z. In the optical device group LG located on at least one side of the display area AA in the third direction Z, the second-type color-resist structure 712b, the composite color-resist structure 711, the first-type color-resist structure 712a, the third-type color-resist structure 712c, and the transparent structure 713 may be sequentially provided in the second direction Y.

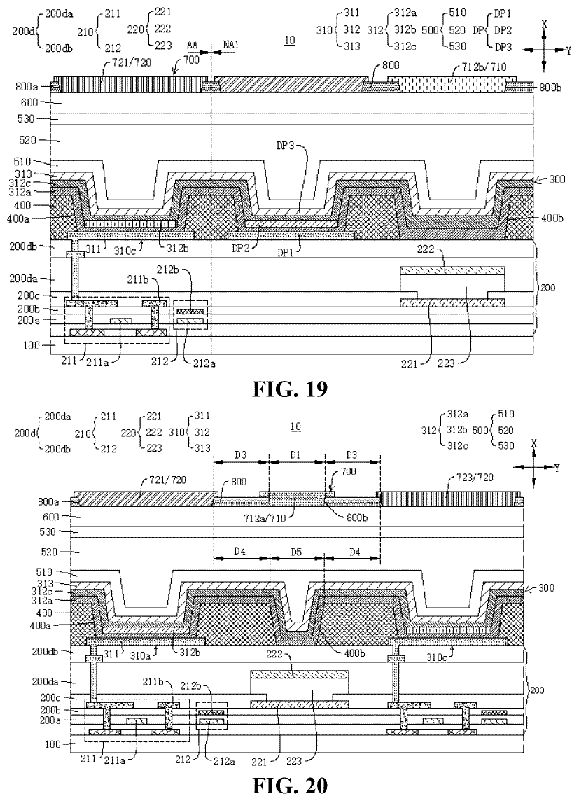

FIG. 19 is a partial cross-sectional view of a display panel 10 provided in yet another embodiment of the present application.

Optionally, the optical device 710 and the photosensitive sensor 220 may be provided adjacent to the display area AA, which may facilitate reducing the bezel of the display panel 10. For example, as shown in FIG. 19, the non-display area NA comprises a dummy pixel area NA1 adjacent to the display area, the display panel 10 further comprises a dummy light-emitting unit DP provided in the dummy pixel area NA1, and the photosensitive sensor 220 and the optical device 710 are at least partially located in the dummy pixel area NA1. As shown in FIG. 19, at least a part of the photosensitive sensor 220 and at least a part of the optical device 710 may be located on a side of the dummy light-emitting unit DP away from the display area AA, and/or at least a part of the photosensitive sensor 220 and at least a part of the optical device 710 may be located on a side of the dummy light-emitting unit DP facing the display area AA (not shown).

Optionally, the structure of the dummy light-emitting unit DP located in the dummy pixel area NA1 may be the same as or similar to the structure of the light-emitting unit 310 located in the display area AA, but the dummy light-emitting unit DP may not emit light, that is, the dummy light-emitting unit DP may not participate in the light-emitting operation of the display panel 10. Exemplarily, in a direction away from the substrate 100, the dummy light-emitting unit DP may comprise a first dummy electrode DP1, a light-emitting material layer DP2, and a second dummy electrode DP3 stacked in sequence. The first dummy electrode DP1 may be made of the same material as the first electrode 311, the second dummy electrode DP3 may be made of the same material as the second electrode 313, and the light-emitting material layer DP2 may be made of the same material and have the same structure as the light-emitting functional layer 312 of at least one light-emitting unit 310. Exemplarily, the light-emitting material layer DP2 may be made of the same material as the light-emitting functional layer 312 of the last light-emitting unit 310 to be fabricated. For example, the light-emitting material layer DP2 may be made of the same material as the light-emitting functional layer 312 of the red light-emitting unit 310a.

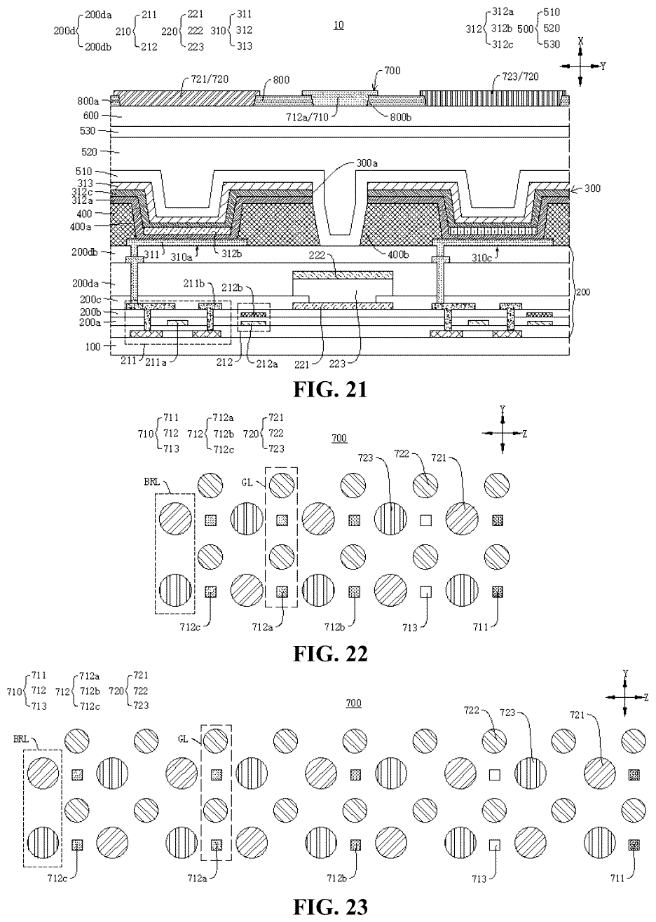

FIG. 20 is a partial cross-sectional view of a display panel 10 provided in yet another embodiment of the present application, FIG. 21 is a partial cross-sectional view of a display panel 10 provided in yet another embodiment of the present application, FIG. 22 is a partial structural schematic diagram of a color-resist layer 700 provided in an embodiment of the present application, and FIG. 23 is a partial structural schematic diagram of a color-resist layer 700 provided in another embodiment of the present application.

In some embodiments, as shown in FIGS. 20 to 23, the optical device group LG may be set in the display area AA, so that the arrangement of the optical device and the photosensitive sensor 220 is less likely to occupy the size of the non-display area NA, which facilitates reduction of the size of the non-display area NA of the display panel 10, thereby facilitating reduction of the bezel size of the display panel 10.

Optionally, in the case that the optical device group LG is set in the display area AA, the distance between the optical device 710 and the color-resist device 720 can be reasonably set to reduce the impact of the light passing through the color-resist device 720 on the photosensitive channel ST, and reduce the impact of the light emitted by the light-emitting unit 310 on the photosensitive channel ST when reflected in the display panel 10, thereby better improving the accuracy of the photosensitive operation of the display panel 10. For example, by reasonably setting the distance between adjacent first openings 800a and second openings 800b (D3 in FIG. 20 can illustrate the distance between adjacent first openings 800a and second openings 800b), and by reasonably setting the distance between the projection of the fourth opening 400b in the first direction X and the projection of the second opening 800b in the first direction X (D4 in FIG. 20 can illustrate the distance between the projection of the fourth opening 400b in the first direction X and the projection of the second opening 800b in the first direction X), the impact of light passing through the color-resist device 720 on the photosensitive channel ST can be reduced, and the impact of light emitted by the light-emitting unit 310 on the photosensitive channel ST when reflected in the display panel 10 can be reduced. The minimum value of the distance between adjacent first openings 800a and second openings 800b can meet the display requirements of the light-emitting unit 310. For example, by reasonably setting the minimum value of the distance between adjacent first openings 800a and second openings 800b, the light-shielding layer 800 can block light emitted by the light-emitting unit 310 at a large angle (for example, the acute angle between the propagation direction and the first direction X is greater than) 45°.

Exemplarily, the distance between adjacent first openings 800a and second openings 800b is greater than or equal to 45 μm to reduce the impact of light passing through the color-resist device 720 on the photosensitive channel ST and reduce the impact of light emitted by the light-emitting unit 310 on the photosensitive channel ST when reflected in the display panel 10.

Optionally, the spacing between each second opening 800b and the adjacent first opening 800a may be the same, and the spacing between each fourth opening 400b and the adjacent third opening 400a may be the same, so that the optical devices 710 and the photosensitive sensors 220 can be provided more evenly in the display area AA, and it can facilitate the arrangement of the light-emitting units 310 in the display area AA. For example, the arrangement of the light-emitting units 310 on the circumferential side of the photosensitive channel ST can be more regular, so that the display panel 10 can have better display uniformity, and the photosensitive channel ST is not easily affected by the light from the surrounding light-emitting units 310 and the color-resist device 720.

Exemplarily, the first opening 800a and the second opening 800b are both located in the display area AA. In the second direction Y and/or the third direction Z, the second opening 800b is adjacent to two first openings 800a, and the distances between the second opening 800b and the two first openings 800a are equal, so that the first opening 800a and the second opening 800b can be arranged more evenly in the second direction Y and the third direction Z, and the second opening 800b can be located in a relatively central position between adjacent first openings 800a, thereby helping improve the display uniformity of the display panel 10 and making the photosensitive channel ST less susceptible to the impact of light from the surrounding light-emitting units 310 and the color-resist device 720.

Optionally, the spacing between adjacent first openings 800a and the spacing between adjacent third openings 400a may be the same, so that the light-emitting units 310 can be provided more evenly in the display area AA, thereby improving the display uniformity of the display panel 10.

Optionally, in the case that the optical device group LG is provided in the display area AA, the size of the second opening 800b may be larger than the size of the fourth opening 400b. For example, the area of the second opening 800b may be larger than the area of the fourth opening 400b. For another example, the second opening 800b may have a first size in the second direction Y and/or the third direction Z, and the fourth opening 400b may have a second size in the second direction Y and/or the third direction Z (D1 in FIG. 20 may indicate the first size, and D5 in FIG. 20 may indicate the second size). The first size may be larger than the second size, so that the fourth opening 400b can have a smaller size, which can facilitate the pixel defining layer 400 in blocking the impact of stray light (for example, light emitted by the light-emitting unit 310 and reflected in the display panel 10; or large-angle ambient light passing through the color-resist device 720) on the photosensitive sensor 220, and also enable the second opening 800b to have a larger size to better compensate for the loss of the inlet light amount caused by the smaller size of the fourth opening 400b, thereby better improving the light-sensing effect of the display panel 10.

Optionally, as shown in FIG. 20, the first common layer 312a, the second common layer 312c, and the second electrode 313 can extend into the fourth opening 400b. The first common layer 312a and the second common layer 312c, with better continuity, can be easily prepared, and the second electrode 313, with better continuity, can have better resistance performance, which helps improve the display uniformity of each light-emitting unit 310.

Optionally, as shown in FIG. 21, at least one of the first common layer 312a, the second common layer 312c, or the second electrode 313 may be provided with a light-transmitting opening 300a located on the side of the fourth opening 400b away from the substrate 100. The setting of the light-transmitting opening 300a makes it less likely that the light-emitting layer 300 will have a significant blocking effect on the light, which facilitates the propagation of light to the photosensitive sensor 220, thereby better improving the photosensitive effect of the display panel 10.

Optionally, at least one color-resist device 720 is provided between two adjacent optical devices 710, allowing the optical devices 710 to be more dispersed within the display area AA. This reduces the risk of decreased display uniformity on the display panel 10 due to overly concentrated placement of the optical devices 710. For example, as shown in FIG. 22, one color-resist device 720 may be provided between two adjacent optical devices 710, or as shown in FIG. 23, more than one color-resist device 720 may be provided between two adjacent optical devices 710.

Optionally, at least two optical devices 710 in the optical device group LG are provided side by side in the second direction Y, and/or at least two optical devices 710 in the optical device group LG are provided side by side in the third direction Z. By arranging the optical devices 710 in the optical device group LG in the second direction Y and/or the third direction Z, the photosensitive channels ST corresponding to the respective optical devices 710 in the optical device group LG can sense light at different positions in the second direction Y and/or the third direction Z, thereby improving the photosensitive effect of the display panel 10.

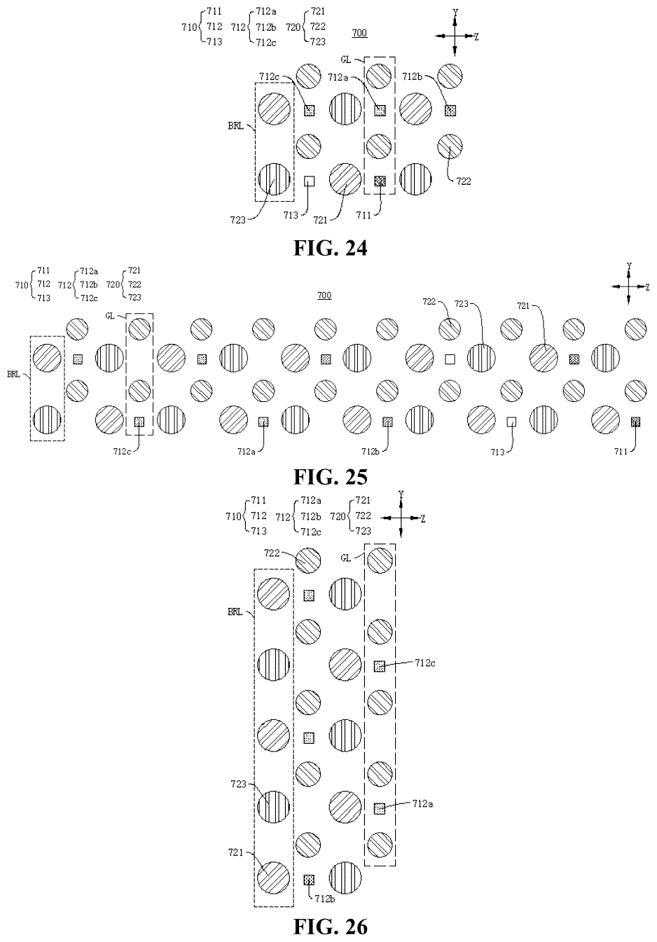

FIG. 24 is a schematic structural diagram of a color-resist layer 700 provided in yet another embodiment of the present application.

Exemplarily, as shown in FIGS. 22 and 23, each optical device 710 in the optical device group LG may be provided side by side in the second direction Y or the third direction Z, or as shown in FIG. 24, a part of the optical devices 710 in the optical device group LG may be provided side by side in the second direction Y, and another part of the optical devices 710 may be provided side by side in the third direction Z, that is, the optical devices 710 in the optical device group LG may not be completely located in the same column in the second direction Y or in the same row in the third direction Z.

Optionally, the first color-resist structure 712a is provided adjacent to the green color-resist structure 722, the second color-resist structure 712b is provided adjacent to the blue color-resist structure 723, and the third color-resist structure 712c is provided adjacent to the red color-resist structure 721.

In the case that the first color-resist structure 712a comprises a green color-resist material, the second color-resist structure 712b comprises a blue color-resist material, and the third color-resist structure 712c comprises a red color-resist material, that is, in the case that the first color-resist structure 712a, the second color-resist structure 712b, and the third color-resist structure 712c are respectively configured to allow green light, blue light, and red light to pass through, light passing through the green color-resist structure 722 is less likely to greatly affect the photosensitivity of the first-type channel ST1, light passing through the blue color-resist structure 723 is less likely to greatly affect the photosensitivity of the second-type channel ST2, and light passing through the red color-resist structure 721 is less likely to significantly affect the photosensitivity of the third-type channel ST3. Therefore, by setting the first-type color-resist structure 712a adjacent to the green color-resist structure 722, the second-type color-resist structure 712b adjacent to the blue color-resist structure 723, and the third-type color-resist structure 712c adjacent to the red color-resist structure 721, the impact of light crosstalk on each photosensitive channel ST can be better reduced.

Optionally, the color-resist devices 720 within the display area AA may be arranged in various ways. For example, a plurality of green color-resist structures 722 may be arranged in the second direction Y to form a green color-resist column GL. The red color-resist structures 721 and the blue color-resist structures 723 may be alternately arranged in the second direction Y to form a blue-red resist column BRL. The green color-resist column GL and the blue-red resist column BRL may be alternately arranged in the third direction Z.

Optionally, the optical device 710 may be located in the green color-resist column GL, and the optical device 710 may be located between two green color-resist structures 722. The optical device 710 may be located in the green color-resist column GL, which may mean that the optical device 710 and the green color-resist structure 722 are arranged side by side in the second direction Y.

Optionally, the optical device 710 may be located in the blue-red resist array BRL (not shown), and the optical device 710 may be located between the blue color-resist structure 723 and the red color-resist structure 721. The optical device 710 may be located in the blue-red resist array BRL, which may mean that the optical device 710 may be arranged side by side with the blue color-resist structure 723 and the red color-resist structure 721 in the second direction Y.

Optionally, at least two optical device groups LG are arranged side by side in the second direction Y, and/or at least two optical device groups LG are arranged side by side in the third direction Z, so that the photosensitive channels ST corresponding to each optical device group LG can sense light at different positions in the second direction Y and/or the third direction Z, so as to enhance the effect of the photosensitive operation of the display panel 10.

FIG. 25 is a schematic partial structural diagram of a color-resist layer 700 provided in yet another embodiment of the present application, and FIG. 26 is a schematic partial structural diagram of a color-resist layer 700 provided in yet another embodiment of the present application.

Optionally, as shown in FIG. 25, at least two optical device groups LG are provided in the second direction Y. Within each optical device group LG, the optical devices 710 are arranged in the third direction Z, and the optical device groups LG are arranged in a staggered manner. As shown in FIG. 26, at least two optical device groups LG are provided in the third direction Z. Within each optical device group LG, the optical devices 710 are arranged in the second direction Y, and the optical device groups LG are arranged in a staggered manner. By arranging the adjacent optical device groups LG in a staggered manner, light crosstalk between photosensitive channels ST corresponding to adjacent optical device groups LG can be effectively reduced, allowing the photosensitive channels ST corresponding to each optical device group LG to perform sensing operations relatively independently, thereby improving the accuracy of the light sensing operation of the display panel 10.

Exemplarily, in the case that the optical device groups LG are arranged in the second direction Y and the optical devices 710 within the optical device group LG are arranged in the third direction Z, the staggered arrangement of the optical device group LG may mean that the individual optical devices 710 within two adjacent optical device groups LG in the second direction Y may not be located in the same column in the second direction Y. For example, in two adjacent optical device groups LG in the second direction Y, the individual optical devices 710 within one of the optical device groups LG may be located in the first column, the third column, the fifth column, the seventh column, and the ninth column, respectively, and the individual optical devices 710 within the other optical device group LG may be located in the second column, the fourth column, the sixth column, the eighth column, and the tenth column, respectively.

The optical device groups LG arranged in the second direction Y may be arranged in a staggered manner (for example, the individual optical devices 710 in the optical device group LG provided in the second direction Y may be located in the same column in the second direction Y), or a part of the optical device groups LG in the optical device group LG arranged in the second direction Y may be arranged in a staggered manner, and another part of the optical device groups LG may be aligned (for example, in the optical device groups LG provided in the second direction Y, the optical device groups LG in odd rows may be aligned, that is, the corresponding optical devices in the optical device groups LG in odd rows provided in the second direction Y may be located in the same column, and the optical device groups LG in even rows may be aligned, that is, the corresponding optical devices 710 in the optical device groups LG in even rows provided in the second direction Y may be located in the same column, while the optical device groups LG in odd rows may be staggered with the optical device groups LG in even rows, that is, the optical devices 710 in the optical device groups LG in odd rows provided in the second direction Y may not be located in the same column as the optical device groups LG in even rows in the second direction Y).

Exemplarily, in the case that the optical device groups LG are arranged in the third direction Z and the optical devices 710 in the optical device group LG are arranged in the second direction Y, the staggered arrangement of the optical device group LG may mean that the individual optical devices 710 in two adjacent optical device groups LG in the third direction Z may not be located in the same row in the third direction Z. For example, in two adjacent optical device groups LG in the third direction Z, the individual optical devices 710 in one of the optical device groups LG may be located in the first row, the third row, the fifth row, the seventh row, and the ninth row, respectively, and the individual optical devices 710 in the other optical device group LG may be located in the second row, the fourth row, the sixth row, the eighth row, and the tenth row, respectively.

The optical device groups LG arranged in the third direction Z may be staggered (for example, the individual optical devices 710 in the optical device group LG provided in the third direction Z may not be located in the same row in the third direction Z), or a part of the optical device groups LG in the optical device group LG arranged in the third direction Z may be staggered, and another part of the optical device groups LG may be aligned (for example, in the optical device groups LG provided along the third direction Z, the optical device groups LG located in odd columns may be aligned, that is, the corresponding optical devices 710 in the optical device groups LG located in odd columns provided along the third direction Z may be located in the same row, and the optical device groups LG in even columns may be aligned, that is, the corresponding optical devices 710 in the optical device groups LG located in even columns provided along the third direction Z may be located in the same row, while the optical device groups LG located in odd columns may be staggered with the optical device groups LG located in even columns, that is, the optical devices 710 in the optical device groups LG located in odd columns provided in the third direction Z may not be located in the same row as the optical devices 710 in the optical device group LG located in the even columns in the third direction Z).

In some embodiments of the present application, the optical device group LG located in the display area AA may not be concentrated in a certain area, that is, the optical device group LG may be provided in a relatively dispersed manner in the display area AA, so that the display uniformity of the display panel 10 is not easily reduced due to the concentrated arrangement of the optical device 710 and the photosensitive sensor 220, and the display panel 10 can detect the light conditions at various positions on a circumferential side of the display panel 10 in a relatively dispersed manner, thereby facilitating improving the accuracy of the light sensing operation of the display panel 10.

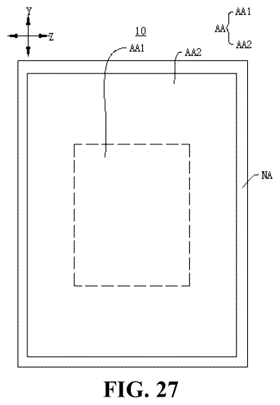

FIG. 27 is a schematic structural diagram of a display panel 10 provided in another embodiment of the present application.

In some embodiments, the display area AA may comprise a central area AA1 and an edge area AA2 surrounding the central area AA1, and the optical device group LG may be provided in both the central area AA1 and the edge area AA2.

Exemplarily, the optical device group LG may be provided in the edge area AA2 located on at least one side of the central area AA1 in the second direction Y, and/or the optical device group LG may be provided in the edge area AA2 located on at least one side of the central area AA1 in the third direction Z.

Optionally, there may be multiple optical device groups LG provided in the central area AA1, and the multiple optical device groups LG provided in the central area AA1 may be distributed at equal intervals to improve the distribution uniformity of the optical device groups LG.

Optionally, there are multiple optical device groups LG in the edge area AA2, and the multiple optical device groups LG provided in the edge area AA2 may be evenly distributed on a circumferential side of the central area AA1 to improve the distribution uniformity of the optical device groups LG.

According to some embodiments of the present application, the present application further provides a display apparatus, which comprises the display panel 10 in any of the aforementioned embodiments.

Since the display apparatus provided in the embodiments of the present application comprises the display panel 10 in any of the aforementioned embodiments, the display apparatus provided in the embodiments of the present application has the beneficial effects of the display panel 10 in any of the aforementioned embodiments, which will not be described in detail here.

The display apparatus provided in the embodiments of the present application may comprise but is not limited to a vehicle-mounted display screen, a mobile phone, a television, a tablet computer, a smart watch, and other devices with a display function.

The above description are only specific embodiments of the present application. Those skilled in the art will clearly understand that for the convenience and brevity of description, the specific working processes of the systems, modules, and units described above can refer to the corresponding processes in the aforementioned method embodiments, and will not be repeated here. It should be understood that the scope of protection of the present application is not limited thereto. Any person skilled in the art can easily think of various equivalent modifications or replacements within the technical scope disclosed in the present application, and these modifications or replacements should be comprised in the scope of protection of the present application.

What is claimed is:

1. A display panel, comprising:
a substrate;
a pixel layer, comprising a plurality of pixel units and a plurality of photosensitive units, each of the plurality of photosensitive units comprising a photosensitive sensor; and
a color-resist layer, provided on a side of the pixel layer away from the substrate, the color-resist layer comprising optical devices each of which overlaps with the photosensitive sensor, the optical devices comprising a composite color-resist structure and a basic color-resist structure, the composite color-resist structure comprising at least two sub-color-resist structures stacked in a first direction and having different filtering wavelength ranges, the first direction being a light-emitting direction of the display panel,
wherein at least one of the at least two sub-color-resist structures has a same material as the basic color-resist structure.

2. The display panel according to claim 1, wherein the optical devices comprise a plurality of the basic color-resist structures that comprise a first-type color-resist structure and a second-type color-resist structure, the first-type color-resist structure allowing light in a first wavelength range to pass through, the second-type color-resist structure allowing light in a second wavelength range to pass through, the second wavelength range intersecting with the first wavelength range, and
at least one of the at least two sub-color-resist structures has a same material as the first-type color-resist structure, and at least one of the at least two sub-color-resist structures has a same material as the second-type color-resist structure.

3. The display panel according to claim 2, wherein the composite color-resist structure allows light in a wavelength range of 450 nm to 560 nm to pass through.

4. The display panel according to claim 2, wherein the first-type color-resist structure comprises a green color-resist material, and the second-type color-resist structure comprises a blue color-resist material.

5. The display panel according to claim 4, wherein the at least one of the at least two sub-color-resist structures having the same material as the first-type color-resist structure is provided on a side, away from the photosensitive sensor, of the at least one of the at least two sub-color-resist structures having the same material as the second-type color-resist structure.

6. The display panel according to claim 4, wherein the basic color-resist structures further comprises a third-type color-resist structure allowing light in a third wavelength range to pass through;
an average value of the first wavelength range is greater than that of the second wavelength range; and
an average value of the third wavelength range is greater than that of the first wavelength range.

7. The display panel according to claim 6, wherein the third-type color-resist structure comprises a red color-resist material.

8. The display panel according to claim 6, wherein the optical devices further comprise a transparent structure allowing visible light to pass through.

9. The display panel according to claim 8, further comprising an optically transparent adhesive layer provided on a side of the composite color-resist structure and the basic color-resist structure away from the photosensitive sensor, wherein the transparent structure and the optically transparent adhesive layer have a same material.

10. The display panel according to claim 8, wherein the first-type color-resist structure, the second-type color-resist structure, the third-type color-resist structure, the composite color-resist structure, and the transparent structure form an optical device group, and the display panel comprises a plurality of the optical device groups; and
the display panel has a display area and a non-display area surrounding the display area, and the plurality of optical device groups are provided in the non-display area.

11. The display panel according to claim 10, wherein the plurality of optical device groups are located on at least one side of the display area in a second direction, and at least two of the plurality of optical device groups are provided side by side in a third direction, any two of the first direction, the second direction, and the third direction intersecting with each other.

12. The display panel according to claim 10, wherein the non-display area comprises a dummy pixel area adjacent to the display area, and the display panel further comprises a dummy light-emitting unit provided in the dummy pixel area, the photosensitive sensors and the optical devices being at least partially located in the dummy pixel area.

13. The display panel according to claim 11, wherein the composite color-resist structure is provided between the first-type color-resist structure and the second-type color-resist structure.

14. The display panel according to claim 13, wherein the first-type color-resist structure is provided between the third-type color-resist structure and the composite color-resist structure.

15. The display panel according to claim 14, wherein in at least one of the optical device groups, the second-type color-resist structure, the composite color-resist structure, the first-type color-resist structure, the third-type color-resist structure, and the transparent structure are provided in sequence in the second direction or the third direction, any two of the first direction, the second direction, and the third direction intersecting with each other.

16. The display panel according to claim 8, wherein the first-type color-resist structure, the second-type color-resist structure, the third-type color-resist structure, the composite color-resist structure, and the transparent structure form an optical device group, and the display panel comprises a plurality of the optical device groups;
the display panel comprises a display area and a non-display area surrounding the display area, and the optical device groups are provided in the display area;
a pixel unit of the pixel units comprises a pixel circuit and a light-emitting unit electrically connected to the pixel circuit, and
the color-resist layer further comprises a color-resist device provided on a side of the light-emitting unit in the first direction, the light-emitting unit and the color-resist device overlapping in the first direction, and at least one of the color-resist devices being provided between adjacent two of the optical devices.

17. The display panel according to claim 16, wherein at least two of the optical devices in at least one of the optical device groups are provided side by side in the second direction, and/or
at least two of the optical devices in at least one of the optical device group are provided side by side in the third direction, any two of the first direction, the second direction, and the third direction intersecting with each other.

18. The display panel according to claim 16, wherein the color-resist device comprises a red color-resist structure, a green color-resist structure, and a blue color-resist structure, the first-type color-resist structure is provided adjacent to the green color-resist structure, the second-type color-resist structure is provided adjacent to the blue color-resist structure, and the third-type color-resist structure is provided adjacent to the red color-resist structure.

19. The display panel according to claim 18, wherein a plurality of the green color-resist structures are provided in the second direction to form a green color-resist column, and the optical devices are located in the green color-resist column and each located between two of the green color-resist structures.

20. A display apparatus, comprising a display panel which comprises:
a substrate;
a pixel layer, comprising a plurality of pixel units and a plurality of photosensitive units, each of the plurality of photosensitive units comprising a photosensitive sensor; and
a color-resist layer, provided on a side of the pixel layer away from the substrate, the color-resist layer comprising optical devices each of which overlaps with the photosensitive sensor, the optical devices comprising a composite color-resist structure and a basic color-resist structure, the composite color-resist structure comprising at least two sub-color-resist structures stacked in a first direction and having different filtering wavelength ranges, the first direction being a light-emitting direction of the display panel,
wherein at least one of the at least two sub-color-resist structures has a same material as the basic color-resist structure.
